(19) United States
(12) Patent Application Publication
(10) Pub. No.: US 2024/0332161 A1
(43) Pub. Date: Oct. 3, 2024

(54) SEMICONDUCTOR DEVICE

(71) Applicant: FUJI ELECTRIC CO., LTD., Kanagawa (JP)

(72) Inventors: Sho NAKAGAWA, Matsumoto-city (JP); Shinji YAMASHINA, Matsumoto-city (JP)

(21) Appl. No.: 18/605,768

(22) Filed: Mar. 14, 2024

(30) Foreign Application Priority Data
Mar. 29, 2023 (JP) 2023-052769
Mar. 4, 2024 (JP) 2024-032448

(51) Int. Cl. H01L 23/52; G01R 19/00

(52) U.S. Cl. CPC H01L 23/52; G01R 19/0046

(57) ABSTRACT

There is provided an semiconductor device comprising: a main element having an upper-surface electrode; a first proximal wiring line connected to the upper-surface electrode; and a first sense wiring line that transmits potential at the first sense position on the upper-surface electrode, wherein the first proximal wiring line is connected to the first proximal position on the upper-surface electrode, and on the upper-surface electrode, a first inter-wiring line distance that is from the first sense position to the first proximal position is different from a half of a maximum distance that is from the first proximal position to an end of the upper-surface electrode.

The contents of the following patent application(s) are incorporated herein by reference: 2023-052769 filed in JP on Mar. 29, 2023.

### BACKGROUND

### 1. Technical Field

The present invention relates to a semiconductor device.

### 2. Related Art

Conventionally, a semiconductor device is known that includes a main MOSFET to drive a load and a sense MOSFET to detect current flowing through the main MOSFET (for example, see patent document 1 and 2).

### PRIOR ART DOCUMENT

### Patent Document

Patent Document 1: Japanese Patent Application Publication No. 2019-144004
Patent Document 2: Japanese Patent Application Publication No. 2007-121052

### BRIEF DESCRIPTION OF THE DRAWINGS

FIG. 1 shows an example of a semiconductor device 100 in accordance with one embodiment of the present invention.

FIG. 2 shows an example of a main element 12 in a cross-sectional view.

FIG. 3 shows an exemplary arrangement of elements on an upper surface of the semiconductor device 100.

FIG. 4 illustrates variation of a resistance value in a path from a first sense position 61 to an output position 71 when the first sense position 61 is changed.

FIG. 5 shows a circuit diagram illustrating resistance between the first sense position 61-1 and the output position 71 when the first sense position 61-1 is provided in a region 101.

FIG. 6 shows a circuit diagram illustrating resistance between the first sense position 61-2 and the output position 71 when the first sense position 61-2 is provided in a region 102.

FIG. 7 shows a circuit diagram illustrating resistance between the first sense position 61-3 and the output position 71 when the first sense position 61-3 is provided in a region 103.

FIG. 8 shows an example of drain-to-source voltage Vds in the main element 12 for each first sense position 61.

FIG. 9 shows an example of drain-to-source voltage Vds in the main element 12 for each first sense position 61 when a resistance value of the upper-surface electrode 60 increases.

FIG. 10 shows variation of sense voltage Vsns before and after the increase in the resistance value Rsw of the upper-surface electrode 60.

FIG. 11 shows variation of sense voltage Vsns before and after the increase in the resistance value Rsw of the upper-surface electrode 60.

FIG. 12 shows variation of sense voltage Vsns before and after the increase in the resistance value Rsw of the upper-surface electrode 60.

FIG. 13 shows variation of sense voltage Vsns before and after the increase in the resistance value Rsw of the upper-surface electrode 60.

FIG. 14 illustrates the relationship between a position Ymos (%) of the first sense position 61 and a variation rate ΔVsns (%) of the sense voltage Vsns.

FIG. 15 illustrates the first sense position 61 in the upper-surface electrode 60.

FIG. 16 shows another exemplary arrangement of the first sense position 61.

FIG. 17 shows another exemplary arrangement of the first sense position 61.

FIG. 18 shows another exemplary arrangement of the first sense position 61.

FIG. 19 shows another exemplary arrangement of the first sense position 61.

FIG. 20 shows another exemplary arrangement of the first sense position 61.

FIG. 21 shows another exemplary arrangement of the first sense position 61.

FIG. 22 shows another exemplary arrangement of the first sense position 61.

FIG. 23 shows another exemplary connection of a sense wiring line 11.

FIG. 24 shows another example of a circuit provided in the semiconductor substrate 10.

FIG. 25 shows another example of the semiconductor device 100.

FIG. 26 shows another configuration example of the semiconductor device 100.

FIG. 27 shows variation of a first sense voltage Vsns1 before and after the increase in the resistance value Rsw of the upper-surface electrode 60.

FIG. 28 shows variation of a second sense voltage Vsns2 before and after the increase in the resistance value Rsw of the upper-surface electrode 60.

FIG. 29 shows variation of a difference voltage Vsnsd (=Vsns2−Vsns1) between the first sense voltage Vsns1 and the second sense voltage Vsns2 before and after the increase in the resistance value Rsw of the upper-surface electrode 60.

FIG. 30 shows another configuration example of the semiconductor device 100.

FIG. 31 shows another exemplary connection of a sense wiring line 11.

FIG. 32 shows an example of an equivalent circuit of the semiconductor device 100 described in FIG. 31.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

When expressions such as “same” or “identical” are used in the present specification, they may include errors resulting from manufacturing variations or the like, in addition to being strictly the same. Such errors are, for example, +5% or less. Also, when expressions relating to angles such as “perpendicular” or “parallel” are used, they may include errors resulting from manufacturing variations or the like, in addition to being strictly 90 degrees or 180 degrees or the like. Such errors are, for example, +5 degrees or less.

When expressions such as “above”, “below”, “upper” or “lower” are used in the present specification, these directions indicate relative directions. For example, these directions do not indicate a direction of gravitational force nor a direction in implementation of an apparatus.

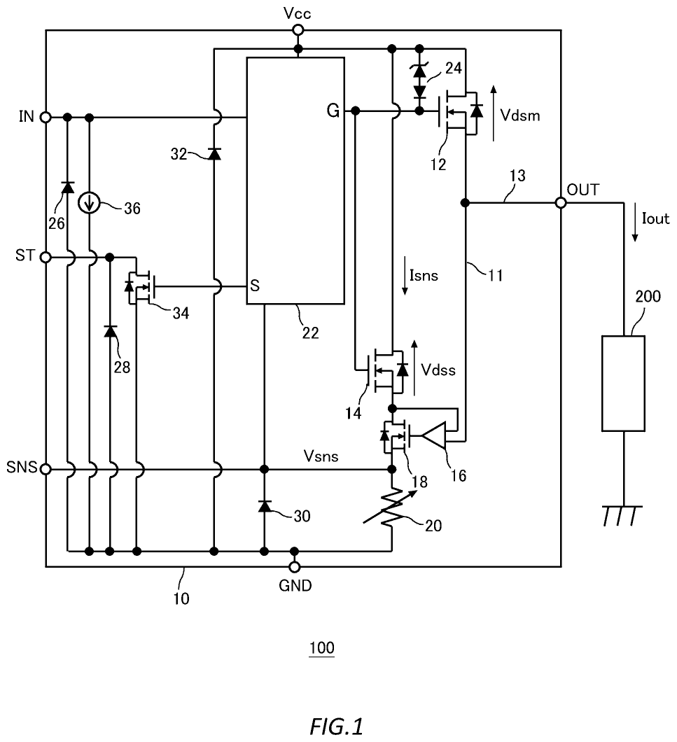

FIG. 1 shows an example of a semiconductor device 100 in accordance with one embodiment of the present invention. A semiconductor device 100 supplies electrical power to a load 200. The semiconductor device 100 of the present example is a semiconductor chip formed on one semiconductor substrate 10. Some components of the semiconductor device 100 may be provided external to the semiconductor substrate 10.

The semiconductor device 100 of the present example is a semiconductor chip that includes an input terminal IN, an output terminal OUT, a high potential terminal Vcc, a low potential terminal GND, and a sense terminal SNS. The semiconductor device 100 may further include a state terminal ST.

The semiconductor device 100 includes a main element 12, a current sensing element 14, an output wiring line 13, and a first sense wiring line 11 provided in the semiconductor substrate 10. The semiconductor device 100 may further include a control unit 22, a sense resistor 20, an amplifier 16, and a MOSFET 18.

Predetermined high potential Vcc is applied to the high potential terminal Vcc. Low potential GND lower than the high potential Vcc is applied to the low potential terminal GND. The low potential GND of the present example is ground potential. Each circuit in the semiconductor device 100 may receive electrical power from the high potential terminal Vcc connected to a power supply.

The semiconductor device 100 operates according to an input signal IN input to the input terminal IN to supply electrical power to the load 200 connected to the output terminal OUT. The input signal IN of the present example may be a signal of a binary logic value which indicates whether to supply electrical power to the load 200 or not.

The main element 12 is provided between the high potential terminal Vcc and the output terminal OUT to switch whether to supply electrical power from the high potential terminal Vcc to the output terminal OUT or not. A source terminal of the main element 12 and the output terminal OUT are connected by output wiring line 13. The output wiring line 13 may include a point-to-point construction of wires or the like. The main element 12 of the present example is a power semiconductor. For example, although the main element 12 is a power MOSFET, it may also be any other power semiconductor such as an IGBT. The control unit 22 of the present example switches an ON/OFF state of the main element 12 according to a logical value of the input signal IN.

Sense current Isns according to the main current Iout flowing through the main element 12 flows through the current sensing element 14. The current sensing element 14 is a power semiconductor that is provided in parallel with the main element 12 and has a similar structure to the main element 12. In the example of FIG. 1, the current sensing element 14 and the main element 12 are both MOSFET. The control unit 22 causes the main element 12 and the current sensing element 14 to transition to an ON-state synchronously and to an OFF-state synchronously.

Sense current Isns corresponding to current obtained by multiplying the main current Iout by a predetermined sense ratio flows through the current sensing element 14. Such a sense ratio is determined by an area ratio between regions through which current flows in the current sensing element 14 and in the main element 12, ON-resistance ratio between the current sensing element 14 and the main element 12 or the like. The sense current Isns is less than the main current Iout. That is, such a sense ratio is less than 1. For example, the sense current Isns may be 1/100 or less or 1/1000 or less of the main current Iout.

A sense resistor 20 is provided between the current sensing element 14 and the low potential terminal GND. The sense resistor 20 causes a voltage drop which corresponds to sense voltage Vsns obtained by multiplying the sense current Isns by the resistance value. The sense current Isns can be calculated from the sense voltage Vsns and the resistance value of the sense resistor 20. The sense terminal SNS may output the sense voltage Vsns to the outside. Since the sense ratio between the sense current Isns and the current sensing element 14 is known, it is possible to calculate the main current Iout from the sense current Isns. The resistance value of the sense resistor 20 may be variable or fixed.

The first sense wiring line 11 is used to equalize potential output by the main element 12 (source potential in the present example) and potential output by the current sensing element 14 (source potential in the present example). Thus, it is possible to match the drain-to-source voltage Vdsm of the main element 12 and the drain-to-source voltage Vdss of the current sensing element 14, and to suppress variation of sense ratio caused by variation of output voltage.

In the present example, a MOSFET 18 is provided between the current sensing element 14 and the sense resistor 20. In addition, an amplifier 16 adjusts voltage to be applied to a gate terminal of the MOSFET 18 so that the voltage applied by the first sense wiring line 11 (for example, source potential of the main element 12) becomes the same as the source potential of the current sensing element 14. With these configurations, it is possible to equalize the potential output by the main element 12 (source potential in the present example) and the potential output by the current sensing element 14 (the source potential in the present example).

The sense voltage Vsns is determined by the product of a resistance value Rsns of the sense resistor 20 and the sense current Isns as defined by the following expression.

Vsns=Rsns×Isns

The sense ratio SR is a ratio of sense current Isns to the output current Iout (Isns/Iout). When ON-resistance of the current sensing element 14 is denoted as Rons and ON-resistance of the main element 12 is denoted as Ronm, each current is expressed by the following expression.

$$Isns = Vdss / Rons$$

$$Iout = Vdsm / Ronm$$

In the present example, Vdsm=Vdss. Therefore, the sense ratio SR is defined by Expression 1.

$$SR = Isns / Iout = Ronm / Rons \qquad Expression 1$$

The control unit 22 may output a state signal S indicating internal state of the semiconductor device 100. The state signal S may be a signal, for example, to indicate that an abnormality such as overcurrent is detected or to indicate whether or not a load 200 is connected to the output terminal OUT, and so on. The semiconductor device 100 may include a MOSFET 34 that switches whether to connect the state terminal ST and the low potential terminal GND or not. The state signal S is applied to a gate terminal of the MOSFET 34. Thus, it is possible to apply, to the state terminal ST, potential according to the internal state of the semiconductor device 100.

A diode may be provided between the low potential terminal GND and each of other terminals to protect internal circuits of the semiconductor device 100 or external devices from overvoltage. In the example of FIG. 1, a diode 26 is provided between the input terminal IN and the low potential terminal GND, a diode 28 is provided between the state terminal ST and the low potential terminal GND, a diode 30 is provided between the sense terminal SNS and the low potential terminal GND, and a diode 32 is provided between the high potential terminal Vcc and the low potential terminal GND. In addition, a protection circuit 24 may also be provided between the high potential terminal Vcc and the gate terminal of the main element 12. The protection circuit 24 may include two diodes arranged in series in an opposite direction. A current source 36 may be provided in the semiconductor device 100 to supply constant current from the input terminal IN to the low potential terminal GND.

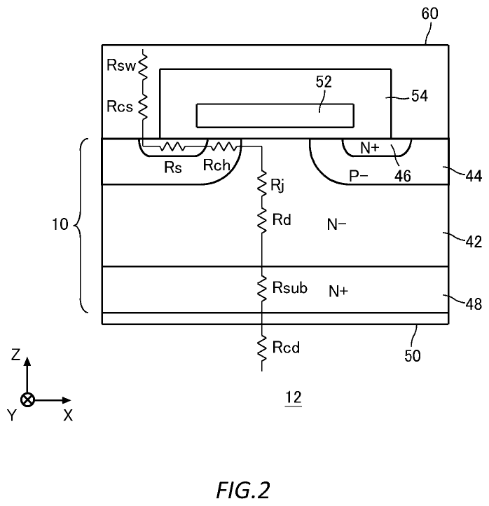

FIG. 2 shows an example of a main element 12 in a cross-sectional view. The current sensing element 14 may also have a similar structure to the main element 12. The main element 12 of the present example includes a semiconductor substrate 10, a gate electrode 52, an insulating layer 54, an upper-surface electrode 60, and a lower-surface electrode 50. The upper-surface electrode 60 of the present example is a source electrode and the lower-surface electrode 50 is a drain electrode. In the present specification, an axis parallel to the depth direction of the semiconductor substrate 10 is denoted as Z-axis, and two axes that are orthogonal to the Z-axis are denoted as X-axis and Y-axis. The X-axis and the Y-axis are orthogonal to each other.

The gate electrode 52 is arranged above the semiconductor substrate 10. The insulating layer 54 is arranged between the gate electrode 52 and the semiconductor substrate 10. The upper-surface electrode 60 is provided on and in contact with an upper surface of the semiconductor substrate 10. The insulating layer 54 is provided between the upper-surface electrode 60 and the gate electrode 52. The lower-surface electrode 50 is provided on and in contact with a lower surface of the semiconductor substrate 10.

The semiconductor substrate 10 is provided with an N-type drift region 42, a P-type base region 44, an N+ type source region 46, and an N+ type drain region 48. The base region 44 and the source region 46 are in contact with the upper-surface electrode 60. The source region 46 and the drift region 42 are separated by the base region 44. On the upper surface of the semiconductor substrate 10, the gate electrode 52 is arranged above the base region 44 between the source region 46 and the drift region 42. When a predetermined ON-voltage is applied to the gate electrode 52, a surface layer of the base region 44 between the source region 46 and the drift region 42 is inverted to an N type region to form a channel. This situation causes the main element 12 to be in an ON-state. The drain region 48 is provided below the drift region 42. When the main element 12 is turned to the ON-state, an output current Iout flows through the lower-surface electrode 50, the drain region 48, the drift region 42, the base region 44, the source region 46, and the upper-surface electrode 60.

The ON-resistance Ronm of the main element 12 is the resistance in a current path running from the lower-surface electrode 50 to the upper-surface electrode 60. A resistance value of the upper-surface electrode 60 is denoted as Rsw, contact resistance between the upper-surface electrode 60 and the source region 46 is denoted as Rcs, resistance in the source region 46 is denoted as Rs, resistance in the base region 44 (channel) is denoted as Rch, resistance in the JFET region is denoted as Rj, resistance in the drift region 42 is denoted as Rd, resistance in the drain region 48 is denoted as Rsub, and contact resistance between the drain region 48 and the lower-surface electrode 50 is denoted as Rcd. The ON-resistance Ronm of the main element 12 is expressed by Expression 2.

$$Ronm = R s w + R c s + R s + R c h + R j + R d + R s u b + R c d \qquad Expression 2$$

Relatively large current may flow through the main element 12. For example, in a load short-circuit mode in which the output terminal OUT is short-circuited to the ground potential or the like, large current may flow through the main element 12. When large current flows through the main element 12 consecutively, the resistance value Rsw at the upper-surface electrode 60 may vary due to electromigration. Electromigration is a phenomenon that causes deformation in a metal electrode by gradual migration of metal ions in the metal electrode. When electromigration proceeds, the resistance value of the upper-surface electrode 60 increases excessively, leading to a possible destruction of the main element 12. Accordingly, it is preferable to be able to detect a symptom of degradation of the upper-surface electrode 60 caused by the electromigration.

As shown in Expression 2, the ON-resistance Ronm varies when the resistance Rsw of the upper-surface electrode 60 varies. As shown in Expression 1, the sense ratio SR varies when the ON-resistance Ronm varies. Thus, it is possible to detect variation of the ON-resistance Ronm by monitoring the variation of the sense ratio SR, and accordingly the symptom of degradation of the upper-surface electrode 60 can be detected.

In the present example, it is preferable to differentiate a ratio of the resistance value Rsw of the upper-surface electrode 60 of the main element 12 to the ON-resistance Ronm of the main element 12 from a ratio of the resistance value Rsw of the upper-surface electrode of the current sensing element 14 to the ON-resistance Rons of the current sensing element 14. By doing so, variation of the ON-resistance Ronm more remarkably appears as variation of the sense ratio SR. For example, variation of the resistance value Rsw of the upper-surface electrode 60 of the main element 12 more remarkably appears in variation of the sense ratio SR even when the resistance value of the upper-surface electrode of the current sensing element 14 varies in a similar way. In the present example, degradation of the upper-surface electrode 60 more remarkably appears as variation of the sense ratio SR, by adjusting a position at which the first sense wiring line 11 is to be connected to the upper-surface electrode 60 of the main element 12.

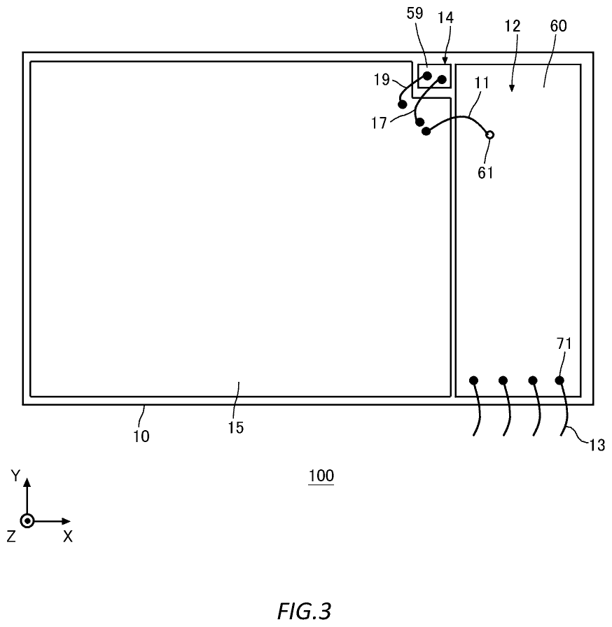

FIG. 3 shows an exemplary arrangement of elements on the upper surface of the semiconductor device 100. FIG. 3 shows the main element 12, the current sensing element 14, and a circuit portion 15 arranged on the upper surface of the semiconductor substrate 10. The circuit portion 15 includes components other than the main element 12 and the current sensing element 14, such as the amplifier 16, the MOSFET 18, and the control unit 22 shown in FIG. 2.

The main element 12 includes the upper-surface electrode 60. The current sensing element 14 includes the upper-surface electrode 59. One or more output wiring lines 13 and a first sense wiring line 11 are connected to the upper-surface electrode 60. The output wiring lines 13 and the first sense wiring line 11 are, for example, a point-to-point construction of wires or the like. A position on the upper-surface electrode 60 at which the output wiring line 13 is connected is denoted as an output position 71. A position on the upper-surface electrode 60 at which the first sense wiring line 11 is connected is denoted as a first sense position 61. In FIG. 3, the position where the sense wiring line 11 is connected to the upper-surface electrode 60 is shown by a white circle, and other connection positions are shown by black circles.

The first sense wiring line 11 is a wiring line to apply potential at the first sense position 61 to the current sensing element 14. The first sense wiring line 11 is connected to the amplifier 16 (see FIG. 1) included in the circuit portion 15. A path length on the upper-surface electrode 60 from the first sense wiring line 11 to the output wiring line 13 varies depending on the arrangement of the first sense position 61 on the upper-surface electrode 60. Accordingly, the resistance value (corresponding to the resistance Rsw) of the path from the first sense wiring line 11 to the output wiring line 13 varies.

A wiring line 17 and a wiring line 19, such as a wire, are connected to the upper-surface electrode 59 of the current sensing element 14. The wiring line 17 is connected to the MOSFET 18 (see FIG. 1) included in the circuit portion 15. The wiring line 19 is connected to an input terminal of the amplifier 16 included in the circuit portion 15. Potential at a position where the wiring line 19 is connected to the upper-surface electrode 59 is approximately the same as potential at the first sense position 61 in the upper-surface electrode 60. The upper-surface electrode 59 is smaller than the upper-surface electrode 60. Therefore, even if the connection positions of the wiring line 17 and the wiring line 19 vary on the upper-surface electrode 59, the resistance value in a path from the position of the wiring line 19 to the connection position of the wiring line 17 in the upper-surface electrode 59 does not vary significantly.

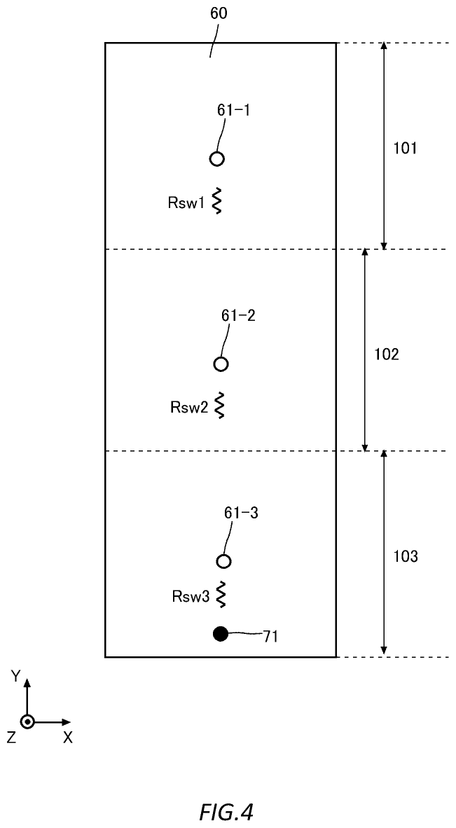

FIG. 4 illustrates variation of a resistance value in a path from the first sense position 61 to the output position 71 when the first sense position 61 is changed. Although the upper-surface electrode 60 of the present example is described to have a rectangular shape in a top view, the upper-surface electrode 60 may have a square or any other shapes. The phrase “in a top view” means to view the upper-surface electrode 60 in a direction perpendicular to the upper surface of the semiconductor substrate 10. In the present example, the upper-surface electrode 60 is virtually divided equally into three regions (region 101, region 102, region 103) in a longer side direction (Y-axis direction). The output position 71 is arranged in the vicinity of an end of the region 103 in the Y-axis direction. The region 101 is the farthest from the region 103, and the region 102 is between the region 101 and the region 103.

Consideration is made about a case in which the first sense position 61 is provided at the center of any of the regions 101-103. The first sense position 61 provided in the region 101 is denoted as a first sense position 61-1, the first sense position 61 provided in the region 102 is denoted as a first sense position 61-2, and the first sense position 61 provided in the region 103 is denoted as a first sense position 61-3.

Resistance in a path between the first sense position 61-3 and the output position 71 is denoted as Rsw3. Since the first sense position 61-3 is arranged in the vicinity of the output position 71, a resistance value of the resistance Rsw3 is relatively small.

Resistance in a path between the first sense position 61-2 and the first sense position 61-3 is denoted as Rsw2. Resistance in a path between the first sense position 61-2 and the output position 71 is expressed by Rsw3+Rsw2.

Resistance in a path between the first sense position 61-1 and the first sense position 61-2 is denoted as Rsw1. Resistance in a path between the first sense position 61-1 and the output position 71 is expressed by Rsw3+Rsw2+Rsw1.

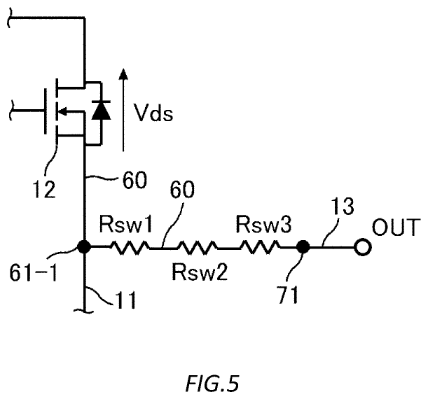

FIG. 5 shows a circuit diagram illustrating the resistance between the first sense position 61-1 and the output position 71 when the first sense position 61-1 is provided in the region 101. As described above, the resistance in the path between the first sense position 61-1 and the output position 71 is expressed by Rsw3+Rsw2+Rsw1.

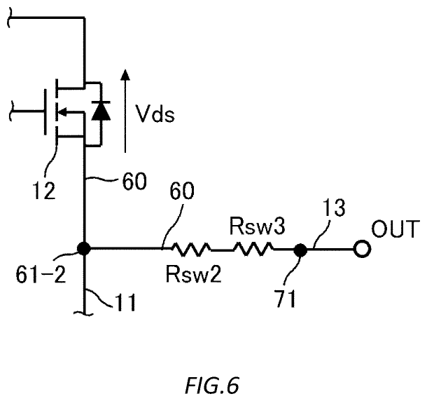

FIG. 6 shows a circuit diagram illustrating the resistance between the first sense position 61-2 and the output position 71 when the first sense position 61-2 is provided in the region 102. As described above, the resistance in the path between the first sense position 61-2 and the output position 71 is expressed by Rsw3+Rsw2.

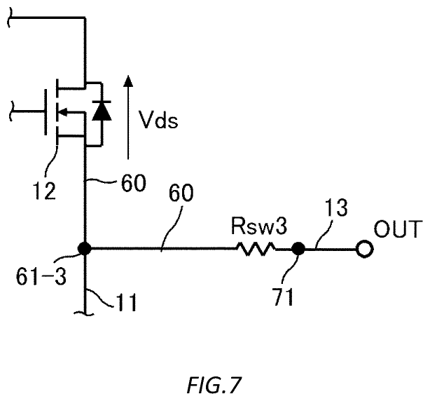

FIG. 7 shows a circuit diagram illustrating the resistance between the first sense position 61-3 and the output position 71 when the first sense position 61-3 is provided in the region 103. As described above, the resistance in the path between the first sense position 61-3 and the output position 71 is Rsw3. In this manner, the resistance value Rsw of the upper-surface electrode 60 can be adjusted by adjusting the first sense position 61 in the upper-surface electrode 60. As described above, it is preferable to arrange the first sense position 61 to a position where variation of the resistance value Rsw of the upper-surface electrode 60 appears more remarkably as variation of the sense ratio SR.

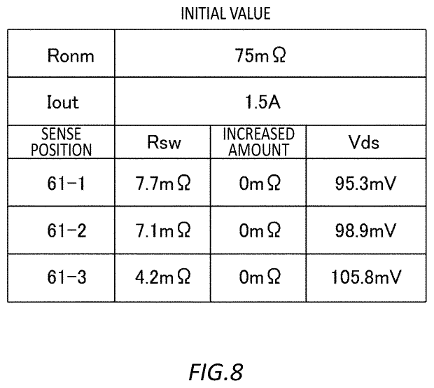

FIG. 8 shows an example of drain-to-source voltage Vds in the main element 12 for each first sense position 61. As shown in FIGS. 5-7, the voltage Vds of the main element 12 is a voltage between the drain terminal of the main element 12 and the first sense position 61. According to such voltage Vds, the drain-to-source voltage of the current sensing element 14 is controlled by the amplifier 16 or the like.

FIG. 8 shows each characteristic value in the initial state of the upper-surface electrode 60 of the semiconductor device 100 before degradation in the resistance value. In the present example, the ON-resistance Ronm of the main element 12 is 75 mΩ and the output current Iout is 1.5 A. In addition, FIG. 8 shows the resistance value Rsw of the upper-surface electrode 60 from each first sense position 61 to the output position 71. The resistance values Rsw of the first sense position 61-1, the first sense position 61-2, and the first sense position 61-3 are 7.7 mΩ, 7.1 mΩ, and 4.2 mΩ, respectively. Here, the voltage Vds at the first sense position 61-1 is 95.3 mV, the voltage Vds at the first sense position 61-2 is 98.9 mV, and the voltage Vds at the first sense position 61-3 is 105.8 mV.

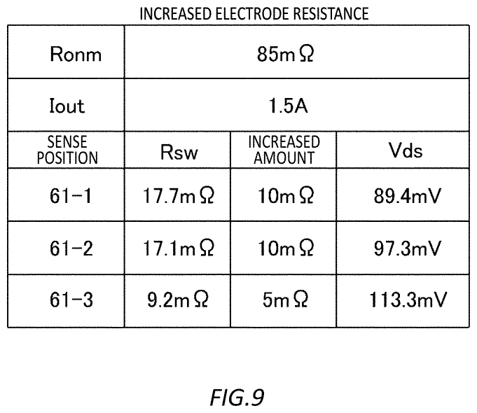

FIG. 9 shows an example of drain-to-source voltage Vds in the main element 12 for each first sense position 61 when a resistance value of the upper-surface electrode 60 increases. In the present example, the ON-resistance Ronm of the main element 12 increases to 85 mΩ. The output current Iout is 1.5 A as is the case with the example of FIG. 8. The resistance values Rsw of the first sense position 61-1, the first sense position 61-2, and the first sense position 61-3 are 17.7 mΩ, 17.1 mΩ, and 9.2 mΩ, respectively. These values are increased with respect to the initial values shown in FIG. 8 by 10 mΩ, 10 mΩ, and 5 mΩ, respectively.

When the resistance value Rsw varies, the voltage Vds at each first sense position 61 also varies. In the present example, the voltage Vds in the first sense position 61-1 is 89.4 mV, the voltage Vds in the first sense position 61-2 is 97.3 mV, and the voltage Vds in the first sense position 61-3 is 113.3 mV.

In an example in which the first sense wiring line 11 is connected to the first sense position 61-1, the voltage Vds of the main element 12 decreases with the increase in the resistance value of the upper-surface electrode 60. In this case, the drain-to-source voltage of the current sensing element 14 also decreases similarly and thus the sense current Isns is decreased. Accordingly, the sense voltage Vsns also decreases.

In an example in which the first sense wiring line 11 is connected to the first sense position 61-2, the voltage Vds of the main element 12 decreases with the increase in the resistance value of the upper-surface electrode 60, as is the case with the example of the first sense position 61-1. However, the decreased amount of the voltage Vds is smaller than that of the example of the first sense position 61-1. Accordingly, the decreased amount of each of the sense current Isns and the sense voltage Vsns also becomes smaller than those of the example of the first sense position 61-1.

In an example in which the first sense wiring line 11 is connected to the first sense position 61-3, the voltage Vds of the main element 12 increases with the increase in the resistance value of the upper-surface electrode 60. In this case, the drain-to-source voltage of the current sensing element 14 also increases similarly and thus the sense current Isns is increased as well. Accordingly, the sense voltage Vsns also increases.

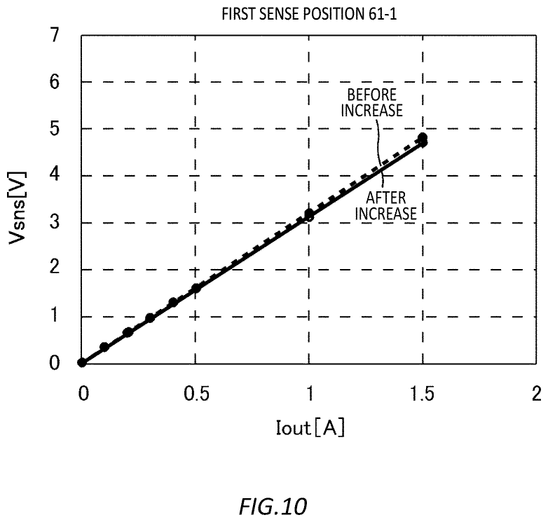

FIG. 10 shows variation of sense voltage Vsns before and after the increase in the resistance value Rsw of the upper-surface electrode 60. FIG. 10 indicates the relationship between the output current Iout and the sense voltage Vsns when the first sense wiring line 11 is connected to the first sense position 61-1. In the present example, the main element 12 is repeatedly turned on and off at a high temperature and for a long time sufficiently to make the resistance value Rsw of the upper-surface electrode 60 increase. In FIG. 10, the characteristics before the increase in the resistance value Rsw is represented by the dashed line and the characteristics after said increase is represented by the solid line. As shown in FIGS. 8 and 9, when the first sense wiring line 11 is connected to the first sense position 61-1, the sense voltage Vsns decreases after the increase in the resistance value Rsw.

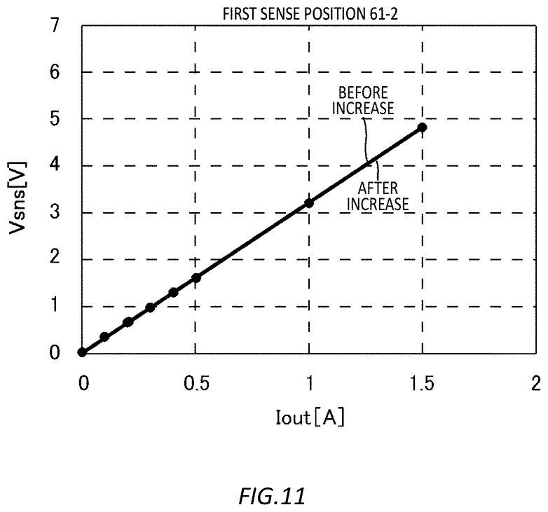

FIG. 11 shows variation of sense voltage Vsns before and after the increase in the resistance value Rsw of the upper-surface electrode 60. FIG. 11 indicates the relationship between the output current Iout and the sense voltage Vsns when the first sense wiring line 11 is connected to the first sense position 61-2. As shown in FIG. 11, the sense voltage Vsns does not vary significantly before and after the increase in the resistance value Rsw.

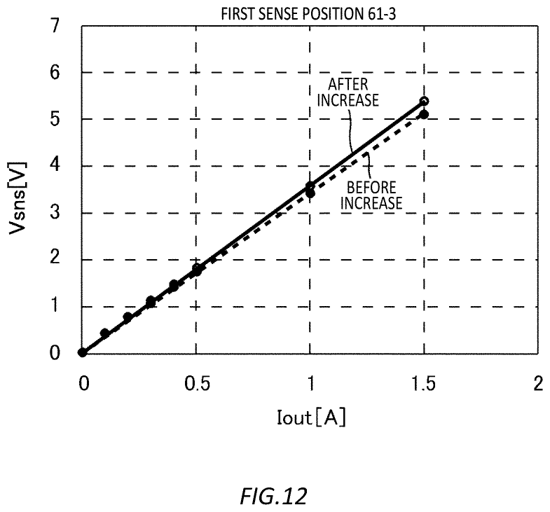

FIG. 12 shows variation of sense voltage Vsns before and after the increase in the resistance value Rsw of the upper-surface electrode 60. FIG. 12 indicates the relationship between the output current Iout and the sense voltage Vsns when the first sense wiring line 11 is connected to the first sense position 61-3. In FIG. 12, the characteristics before the increase in the resistance value Rsw is represented by the dashed line and the characteristics after said increase is represented by the solid line. As shown in FIGS. 8 and 9, when the first sense wiring line 11 is connected to the first sense position 61-3, the sense voltage Vsns increases after the increase in the resistance value Rsw.

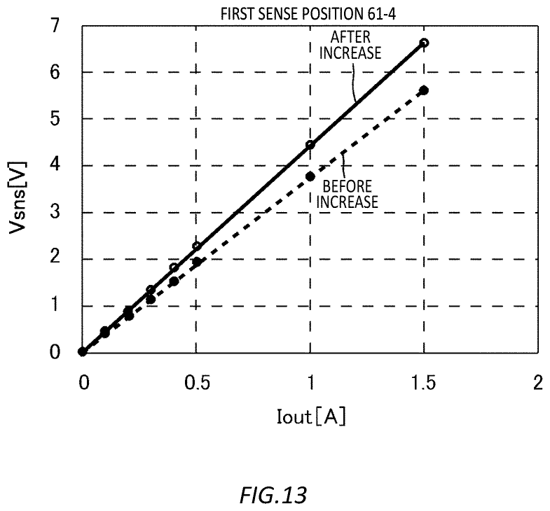

FIG. 13 shows variation of sense voltage Vsns before and after the increase in the resistance value Rsw of the upper-surface electrode 60. FIG. 13 indicates the relationship between the output current Iout and the sense voltage Vsns when the first sense wiring line 11 is connected to the first sense position 61-4. The first sense position 61-4 is arranged closer to the output position 71 than the first sense position 61-3. The first sense position 61-4 of the present example is arranged side-by-side with the output position 71 in the X-axis direction. When the first sense wiring line 11 is connected to the first sense position 61-4, the sense voltage Vsns increases after the increase in the resistance value Rsw. Since the first sense position 61-4 is arranged in the vicinity of the output position 71, the variation of the sense voltage Vsns before and after the increase in the resistance value Rsw is even greater.

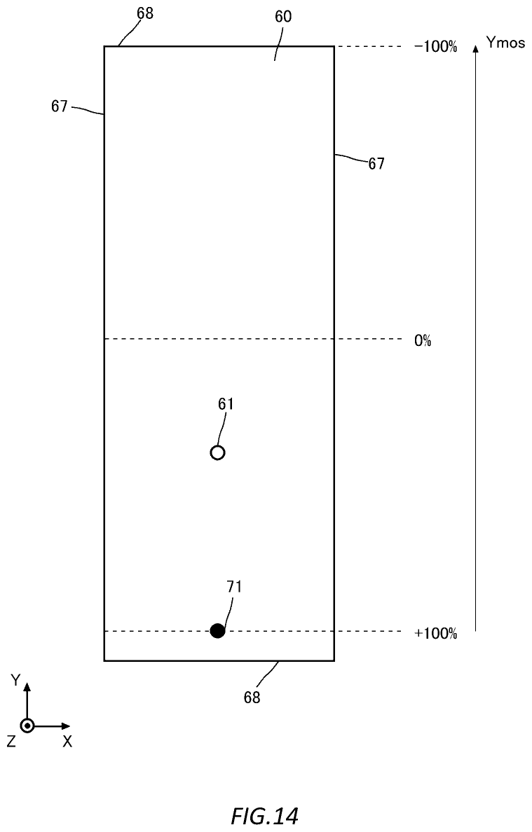

FIG. 14 illustrates the relationship between a position Ymos (%) of the first sense position 61 and a variation rate ΔVsns (%) of the sense voltage Vsns. The upper-surface electrode 60 of the present example includes a pair of longer sides 67 parallel to the Y-axis and a pair of shorter sides 68 parallel to the X-axis. The output position 71 is provided in the vicinity of either one of the shorter sides 68. In the Y-axis direction, a position where the output position 71 is provided is denoted as the position of +100% and a position of the shorter side 68 opposite to the output position 71 is denoted as the position of −100%. The center between the output position 71 and the shorter side 68 is denoted as the position of 0%.

In the present example, the maximum value of variation of the voltage Vds of the main element 12 is denoted as ΔVdsm. As shown in FIGS. 10-13, variation of the voltage Vds is maximized when the first sense position 61 is arranged in the position of Ymos=+100%. The variation ΔVds of the voltage Vds of the main element 12 is expressed by Expression 3, using the position Ymos of the first sense position 61.

$$Δ V d s = Δ Vdsm \times Ymos \qquad Expression 3$$

From Expression 1 or the like described above, the sense voltage Vsns is expressed by Expression 4.

$$Vsns = Iout \times Rsns \times SR \qquad Expression 4$$

Iout is a constant value without significant variation even if the resistance value Rsw of the main element 12 varies. The sense ratio SR is, as described above, the ratio Ronm/Rons of the ON-resistance Ronm of the main element 12 to the ON-resistance Rons of the current sensing element 14. The current flowing through the current sensing element 14 is much smaller than the current flowing through the main element 12 and therefore electromigration is less likely to occur on the upper-surface electrode 59 of the current sensing element 14. Accordingly, the ON-resistance Rons of the current sensing element 14 does not vary significantly. In addition, since the upper-surface electrode 59 of the current sensing element 14 is very small, there is little variation of the resistance value caused by variation of connection positions of the wiring line 19 or the like.

Thus, the sense voltage Vsns varies according to the variation ratio of the ON-resistance Ronm of the main element 12. When the sense voltage before the variation in ON-resistance Ronm is denoted as Vsns1 and the sense voltage after the variation is denoted as Vsns2, these are expressed by the following expression.

$$Vsns 1 = Iout \times Rsns \times SR$$

$$Vsns 2 = Iout \times Δ Vds \times Rsns \times SR = Iout \times Δ Vdsm \times Ymos \times Rsns \times SR$$

Since the output current Iout and the sense resistor Rsns are constant values, the variation rate ΔVsns=Vsns2/Vsns1 of the sense voltage is expressed by the following expression.

$$Δ Vsns = Δ Vdsm \times Ymos$$

The greater the variation rate ΔVsns of the sense voltage is, the easier it becomes to sense variation of the resistance value Rsw of the upper-surface electrode 60. It is preferable to adjust the first sense position 61 so that the variation rate ΔVsns becomes large in the semiconductor device 100.

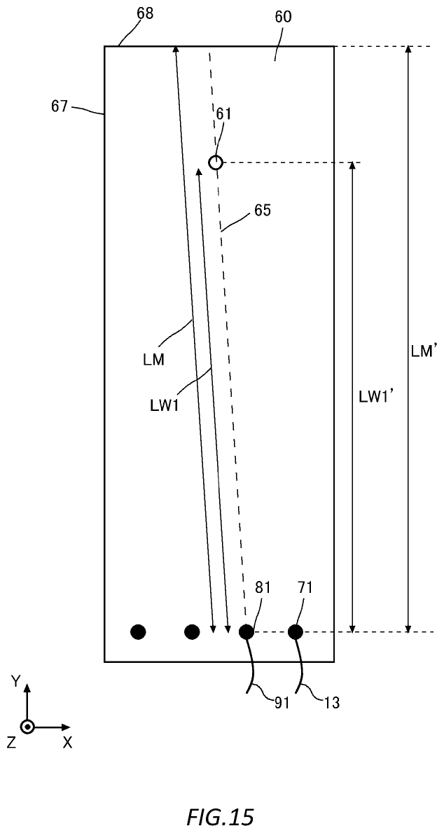

FIG. 15 illustrates the first sense position 61 in the upper-surface electrode 60. In the present example, a wiring line among one or more output wiring lines 13 that has a shortest distance between its connection position to the upper-surface electrode 60 and the first sense position 61 is denoted as the first proximal wiring line 91. A position at which the first proximal wiring line 91 is connected to the upper-surface electrode 60 is denoted as the first proximal position 81.

A distance on the upper-surface electrode 60 from the first sense position 61 to the first proximal position 81 is denoted as the first inter-wiring line distance LW1. In addition, a maximum distance from the first proximal position 81 to an end of the upper-surface electrode 60 is denoted as LM. A straight line that connects the first proximal position 81 with the first sense position 61 is denoted as a straight line 65. The maximum distance LM may represent a maximum distance from the first proximal position 81 to the end of the upper-surface electrode 60 in a direction parallel to the straight line 65.

When the upper-surface electrode 60 has a rectangular shape, the first inter-wiring line distance LW1 may be substituted with a distance LW1′ between the first proximal position 81 and the first sense position 61 in a direction parallel to the longer side 67 (Y-axis direction in FIG. 15). In addition, the maximum distance LM described above may be substituted with a maximum distance LM′ between the first proximal position 81 and the end of the upper-surface electrode 60 in a direction parallel to the longer side 67.

On the upper-surface electrode 60, the first inter-wiring line distance LW1 from the first sense position 61 to the first proximal position 81 is different from a half (LM/2) of the maximum distance LM from the first proximal position 81 to the end of the upper-surface electrode 60. That is, the first sense position 61 is arranged between the first proximal position 81 and the end of the upper-surface electrode 60 at a position other than the center. With such an arrangement, variation of resistance value Rsw of the upper-surface electrode 60 appears as variation of the sense ratio SR (sense voltage Vsns), as described in FIGS. 10-14. Accordingly, the variation of the resistance value Rsw of the upper-surface electrode 60 can be sensed by detecting the variation of the sense ratio SR (or sense voltage Vsns). Since the resistance value variation of the resistance value Rsw of the upper-surface electrode 60 can be sensed at an early stage, it is possible to prevent destruction of the main element 12.

As described in FIGS. 10-14, the further the position of the first sense position 61 Ymos is from the position of 0%, the more greatly the sense ratio SR (or the sense voltage Vsns) varies according to variation of the resistance value Rsw of the upper-surface electrode 60. The first inter-wiring line distance LW1 may be equal to or more than 0 times and equal to or less than ¼ times the maximum distance LM. That is, Ymos shown in FIG. 14 may be +100% or less and +50% or more. The first inter-wiring line distance LW1 may be equal to or less than ⅛ times, equal to or less than 1/10 times, or equal to or less than 1/20 times the maximum distance LM. That is, Ymos shown in FIG. 14 may be +75% or more, +80% or more, or +90% or more.

The first inter-wiring line distance LW1 may be equal to or more than ¾ times and equal to or less than 1 times the maximum distance LM. That is, Ymos shown in FIG. 14 may be −100% or more and −50% or less. The first inter-wiring line distance LW1 may be equal to or more than ⅞ times, equal to or more than 9/10 times, or equal to or more than 19/20 times the maximum distance LM. That is, Ymos shown in FIG. 14 may be −75% or less, −80% or less, or −90% or less.

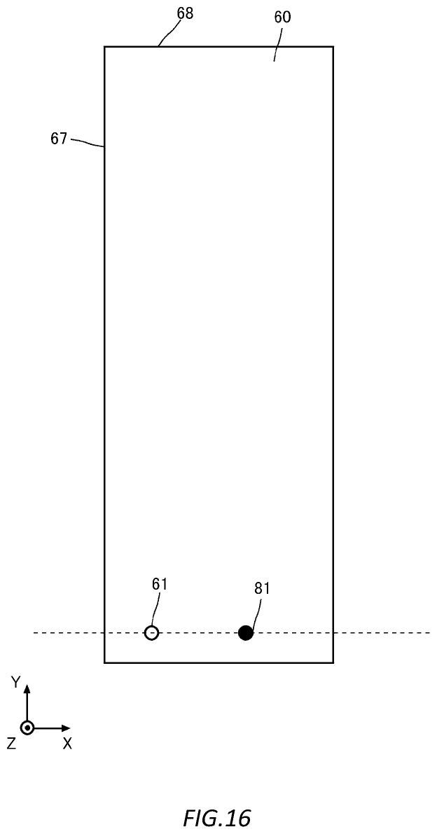

FIG. 16 shows another exemplary arrangement of the first sense position 61. The first sense position 61 of the present example is arranged along the first direction that is parallel to the shorter side 68 of the upper-surface electrode 60. The sense ratio SR (sense voltage Vsns) of the present example varies as shown in FIG. 13. Accordingly, variation of the sense ratio SR (sense voltage Vsns) according to variation of the resistance value Rsw of the upper-surface electrode 60 can be maximized, allowing easier sensing of the variation of resistance value Rsw of the upper-surface electrode 60.

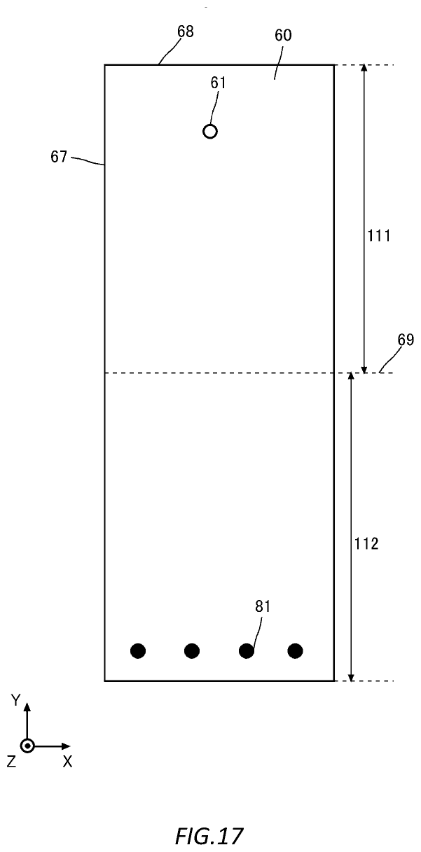

FIG. 17 shows another exemplary arrangement of the first sense position 61. In the present example, the upper-surface electrode 60 is virtually divided equally into a plurality of equivalent regions by a straight line 69 that is parallel to any of the sides of the upper-surface electrode 60. In FIG. 17, the upper-surface electrode 60 is divided equally into two regions by the straight line 69 that is parallel to the shorter side 68. Equally divided two regions of the upper-surface electrode 60 are denoted as the first region 111 and the second region 112.

In the present example, the first sense position 61 is arranged in the first region 111 and the first proximal position 81 is arranged in the second region 112. Accordingly, variation of the resistance value Rsw of the upper-surface electrode 60 can be sensed from variation of the sense ratio SR. The upper-surface electrode 60 may be divided into more regions by a plurality of straight lines 69. For example, the upper-surface electrode 60 may be divided into N regions (N is an integer greater than or equal to 3) in the Y-axis direction by a plurality of straight lines 69. N may be an integer greater than or equal to 4, an integer greater than or equal to 5, or an integer greater than or equal to 10. Also in this case, a region provided with the first proximal position 81 is denoted as second region 112, and a region in which the first sense position 61 is arranged is denoted as the first region 111. The first region 111 may be the farthest region from the second region 112 among the plurality of regions.

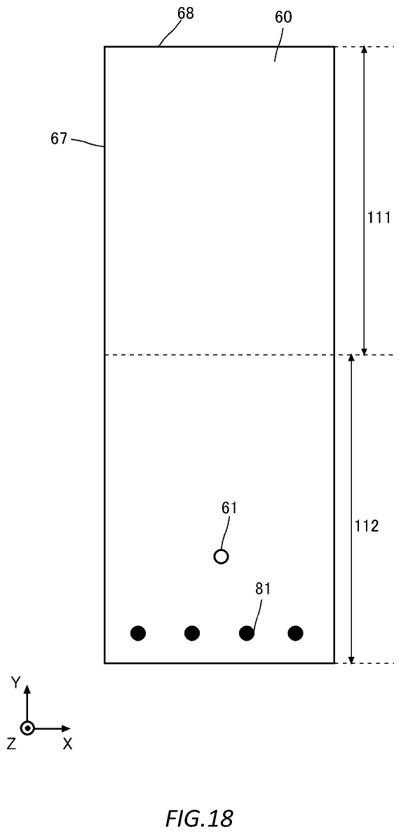

FIG. 18 shows another exemplary arrangement of the first sense position 61. Also in the present example, the upper-surface electrode 60 is virtually divided by the straight line 69 in the same way as the example of FIG. 17. In the present example, both of the first sense position 61 and the first proximal position 81 are arranged in the same second region 112. Accordingly, variation of the resistance value Rsw of the upper-surface electrode 60 can be sensed by variation of the sense ratio SR. The upper-surface electrode 60 may be divided into more regions by a plurality of straight lines 69. For example, the upper-surface electrode 60 may be divided into N regions (N is an integer greater than or equal to 3) in the Y-axis direction by a plurality of straight lines 69. N may be an integer greater than or equal to 4, an integer greater than or equal to 5, or an integer greater than or equal to 10. Also in this case, the first sense position 61 and the first proximal position 81 may be arranged in the same second region 112. The second region 112 may be an endmost region arranged in the Y-axis direction or may be a region that is not arranged at the end.

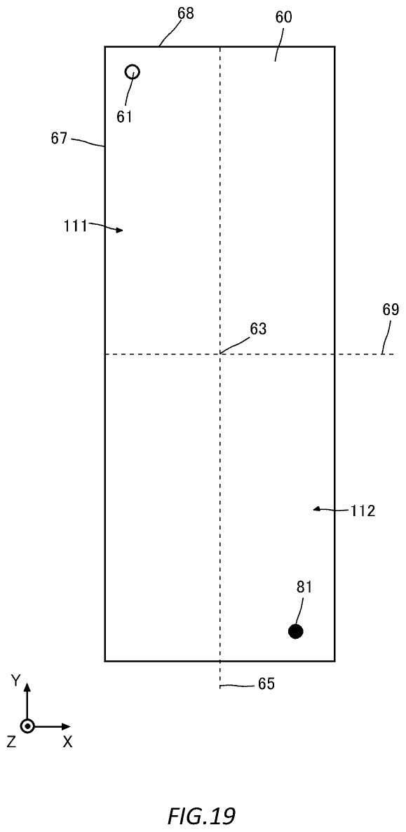

FIG. 19 shows another exemplary arrangement of the first sense position 61. In the present example, the upper-surface electrode 60 is divided equally into a plurality of regions in the Y-axis direction by a straight line 69 that is parallel to the first side (for example, a shorter side 68) of the upper-surface electrode 60, and also divided equally into a plurality of regions in the X-axis direction by a straight line 65 that is parallel to the second side (for example, a longer side 67) that is not parallel to the first side. In the example of FIG. 19, the upper-surface electrode 60 is divided equally into two regions each in the X-axis direction and the Y-axis direction.

In the present example, the first sense position 61 is arranged in the first region 111 and the first proximal position 81 is arranged in the second region 112. The first region 111 and the second region 112 are regions diagonally arranged to each other in the upper-surface electrode 60. That is, the first region 111 and the second region 112 are point-symmetrically arranged around the center point 63 of the upper-surface electrode 60. Accordingly, variation of the resistance value Rsw of the upper-surface electrode 60 can be sensed by variation of the sense ratio SR.

The upper-surface electrode 60 may be divided into more regions by a plurality of straight lines 69 and a plurality of straight lines 65. For example, the upper-surface electrode 60 may be divided into N regions (N is an integer greater than or equal to 3) in the Y-axis direction by a plurality of straight lines 69, and divided into M regions (M is an integer greater than or equal to 3) in the X-axis direction by a plurality of straight lines 65. Each of N and M may be an integer greater than or equal to 4, an integer greater than or equal to 5, or an integer greater than or equal to 10. N and M may be the same integer or different integers. Also in this case, a region provided with the first proximal position 81 is denoted as second region 112, and a region in which the first sense position 61 is arranged is denoted as the first region 111. The first region 111 and the second region 112 may be the regions arranged diagonally (point-symmetrically) to each other. Each of the first region 111 and the second region 112 may be a region that includes any of the sides of the upper-surface electrode 60, or may be a region that includes any corner of the upper-surface electrode 60. Accordingly, a distance between the first region 111 and the second region 112 becomes longer, allowing easier sensing of variation of resistance value Rsw of the upper-surface electrode 60.

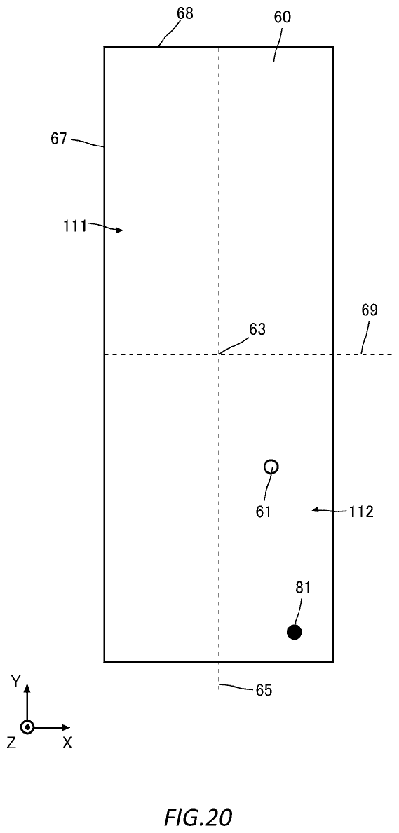

FIG. 20 shows another exemplary arrangement of the first sense position 61. In the present example, the upper-surface electrode 60 is divided equally into a plurality of regions (divided equally into two in FIG. 20) in the Y-axis direction by a straight line 69 that is parallel to the first side (for example, shorter side 68) of the upper-surface electrode 60, and also divided equally into a plurality of regions (divided equally into two in FIG. 20) in the X-axis direction by a straight line 65 that is parallel to the second side (for example, longer side 67) that is not parallel to the first side.

In the present example, both of the first sense position 61 and the first proximal position 81 are arranged in the same second region 112. Accordingly, variation of the resistance value Rsw of the upper-surface electrode 60 can be sensed by variation of the sense ratio SR.

The upper-surface electrode 60 may be divided into more regions by a plurality of straight lines 69 and a plurality of straight lines 65. For example, the upper-surface electrode 60 may be divided into N regions (N is an integer greater than or equal to 3) in the Y-axis direction by a plurality of straight lines 69, and divided into M regions (M is an integer greater than or equal to 3) in the X-axis direction by a plurality of straight lines 65. Each of N and M may be an integer greater than or equal to 4, an integer greater than or equal to 5, or an integer greater than or equal to 10. N and M may be the same integer or different integer. Also in this case, the first proximal position 81 and the first sense position 61 may be provided in the same second region 112. The second region 112 may be a region that includes any of the sides of the upper-surface electrode 60, or may be a region that includes any corner of the upper-surface electrode 60.

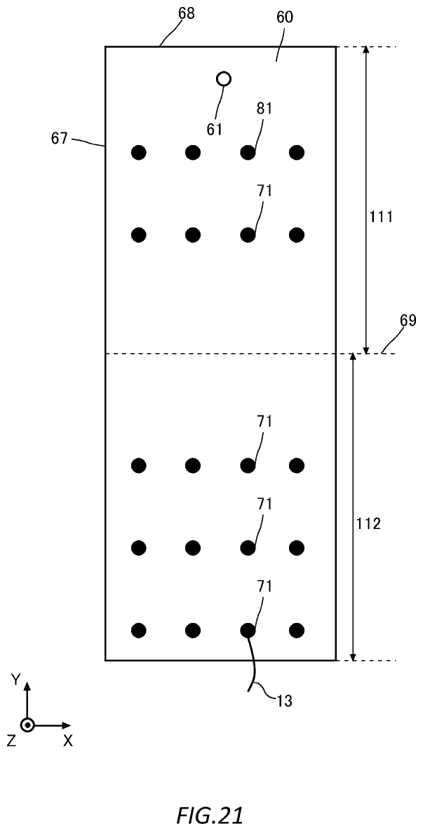

FIG. 21 shows another exemplary arrangement of the first sense position 61. In the present example, the upper-surface electrode 60 is virtually divided by a straight line 69 that is parallel to any of the sides of the upper-surface electrode 60. In FIG. 21, the upper-surface electrode 60 is divided equally into a plurality of regions (divided equally into two in FIG. 21) by the straight line 69 that is parallel to the shorter side 68. Equally divided two regions of the upper-surface electrode 60 are denoted as the first region 111 and the second region 112.

In the present example, each of the first region 111 and the second region 112 has one or more output positions 71 arranged therein. An output wiring line 13 is connected to each output position 71. In the present example, the number of output wiring lines 13 connected to the second region 112 (that is, the number of the output positions 71) is greater than the number of output wiring lines 13 connected to the first region 111 (that is, the number of the output positions 71).

The first sense position 61 is arranged in the first region 111. Note that the relationship between the first sense position 61 and the first proximal position 81 is the same as any example described in the present specification. The first sense position 61 may be arranged most proximal to the shorter side 68 in the Y-axis direction than any other output positions 71. That is, the first sense position 61 may be arranged in the Y-axis direction between the output position 71 closest to either one of the shorter sides 68 and said one shorter side 68. In the present example as well, variation of the resistance value Rsw of the upper-surface electrode 60 can be sensed by variation of the sense ratio SR.

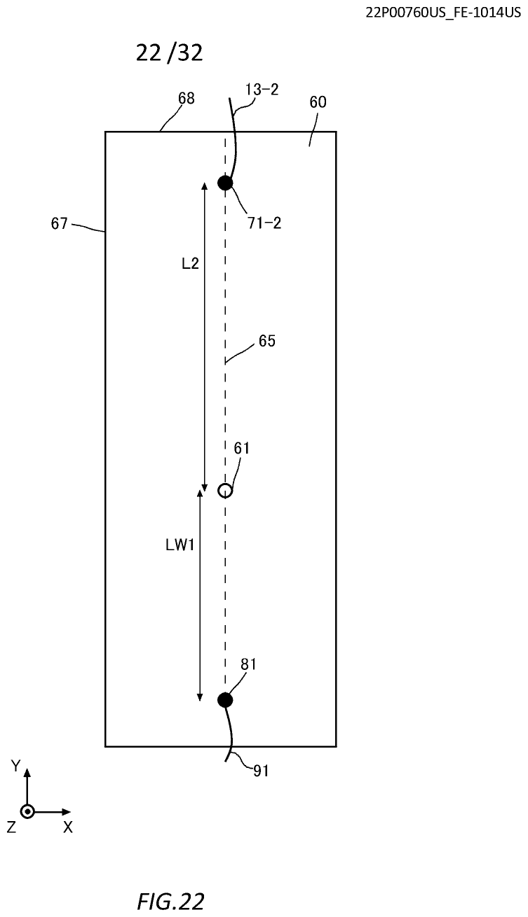

FIG. 22 shows another exemplary arrangement of the first sense position 61. In the present example, an output wiring line, among a plurality of output wiring lines 13, that has the second-shortest distance L2 between its connection position to the upper-surface electrode 60 and the first sense position 61 is denoted as the second wiring line 13-2. The distance between the output position 71-2 of the second wiring line 13-2 and the first sense position 61 is denoted as L2. The distance L2 is longer than the first inter-wiring line distance LW1. By such an arrangement as well, variation of the resistance value Rsw of the upper-surface electrode 60 can be sensed by variation of the sense ratio SR. The distance L2 may be equal to or more than twice, equal to or more than three times, or equal to or more than five times the first inter-wiring line distance LW1. The longer the distance L2 is compared to the first inter-wiring line distance LW1 (that is, the more the first sense position 61 is offset in arrangement), the more easily the variation of the resistance value Rsw of the upper-surface electrode 60 is sensed by the variation of the sense ratio SR.

The first sense position 61 may be arranged between the first proximal position 81 and the output position 71-2 in the Y-axis direction. The first proximal position 81, the first sense position 61, and the output position 71-2 may be arranged on the same straight line 65. The straight line 65 may run through any part of each connection position. The straight line 65 may run through the center of each connection position.

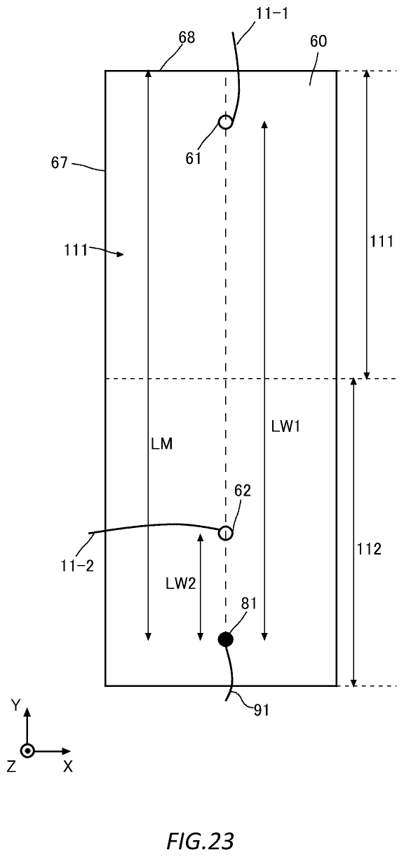

FIG. 23 shows another exemplary connection of a sense wiring line 11. The first sense wiring line 11-1 and the second sense wiring line 11-2 are connected to the upper-surface electrode 60 of the present example. A position at which the first sense wiring line 11-1 is connected to the upper-surface electrode 60 is denoted as the first sense position 61, and a position at which the second sense wiring line 11-2 is connected to the upper-surface electrode 60 is denoted as the second sense position 62. The second sense wiring line 11-2 is a wiring line to apply potential at the second sense position 62 to the current sensing element 14.

A distance from the second sense position 62 to the first proximal position 81 is denoted as the second inter-wiring line distance LW2. The second inter-wiring line distance LW2 is different from the first inter-wiring line distance LW1. The second inter-wiring line distance LW2 may be equal to or more than twice, equal to or more than four times, or equal to or more than ten times the first inter-wiring line distance LW1.

The first inter-wiring line distance LW1 may be more than a half of the maximum distance LM and may be equal to or less than 1 times the maximum distance LM. The second inter-wiring line distance LW2 may be shorter than the half of the maximum distance LM and may be equal to or more than 0 times the maximum distance LM. With such an arrangement, when the resistance value Rsw of the upper-surface electrode 60 increases, the voltage Vds at the first sense position 61 decreases and the voltage Vds at the second sense position 62 increases. Accordingly, the increase in the resistance value Rsw of the upper-surface electrode 60 can be accurately detected by comparing the variation of voltage Vds at the first sense position 61 with the variation of voltage Vds at the second sense position 62. For example, if the voltage Vds at the first sense position 61 and the voltage Vds at the second sense position 62 both increase or decrease, it can be determined that such variation of voltage is not due to variation of the resistance value Rsw of the upper-surface electrode 60.

The first inter-wiring line distance LW1 may be equal to or more than ¾ times, equal to or more than ⅞ times, equal to or more than 9/10 times, or equal to or more than 19/20 times the maximum distance LM. The second inter-wiring line distance LW2 may be equal to or less than ¼ times, equal to or less than ⅛ times, equal to or less than 1/10 times, or equal to or less than 1/20 times the maximum distance LM. The variation of the resistance value Rsw of the upper-surface electrode 60 can be detected more accurately by bringing one of the first sense position 61 and the second sense position 62 closer to the first proximal position 81 and bringing the other away from the first proximal position 81.

When the upper-surface electrode 60 is virtually divided equally into a plurality of regions (for example, divided equally into two) by a straight line 69 that is parallel to any of the sides of the upper-surface electrode 60, the first sense position 61 and the second sense position 62 may be arrange in the regions different from each other. In the present example, the first sense position 61 is arranged in the first region 111 and the first proximal position 81 is arranged in the second region 112. The upper-surface electrode 60 may be divided into more regions by a plurality of straight lines 69. For example, the upper-surface electrode 60 may be divided into N regions (N is an integer greater than or equal to 3) in the Y-axis direction by a plurality of straight lines 69. N may be an integer greater than or equal to 4, an integer greater than or equal to 5, or an integer greater than or equal to 10. One or more other regions may be interposed between the first region 111 provide with the first sense position 61 and the second region 112 provided with the second sense position 62. Each of the first region 111 and the second region 112 may include a shorter side 68.

As is the case with the first sense position 61 described in FIG. 19, the first sense position 61 may be provided in the first region 111 that is diagonally opposite to the second region 112 provided with the first proximal position 81. As is the case with the first sense position 61 described in FIG. 20, the second sense position 62 may be provided in the same second region 112 as the first proximal position 81.

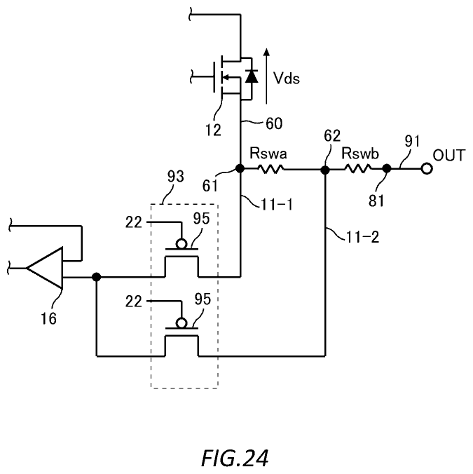

FIG. 24 shows another example of a circuit provided in the semiconductor substrate 10. The semiconductor device 100 of the present example includes a selector 93 in addition to the components described in FIGS. 1-23. The selector 93 selects either voltage in the first sense position 61 or voltage in the second sense position 62 described in FIG. 23 to apply the selected voltage to the current sensing element 14. The selector of the present example selects either one of the voltages to input the selected voltage to the amplifier 16. In FIG. 24, a resistance value of the upper-surface electrode 60 from the first sense position 61 to the second sense position 62 is denoted as Rswa, and a resistance value of the upper-surface electrode 60 from second sense position 62 to the first proximal position 81 is denoted as Rswb.

The control unit 22 shown in FIG. 1 may control the selector 93 to select either one of the voltages. The selector 93 of the present example includes MOSFETs 95 that switch whether to connect each of the first sense position 61 and the second sense position 62 to the amplifier 16 or not. By selectively causing either one of the MOSFETs 95 to be in the ON-state, the voltage at the sense position is input to the amplifier 16.

Upon operation of the semiconductor device 100, the control unit 22 may select a preset one of the first sense position 61 and the second sense position 62 to be connected to the amplifier 16. The control unit 22 may control the selector 93 to select another one of the first sense position 61 and the second sense position 62 when variation of the sense ratio SR (or sense voltage Vsns) is sensed. The control unit 22 may store therein an initial value of the sense ratio SR (or sense voltage Vsns) for each of the first sense position 61 and the second sense position 62. Preferably, the first sense position 61 and the second sense position 62 are arranged so that their signs of variation of the sense ratio SR (or sense voltage Vsns) become different, as described in examples of FIG. 10 and FIG. 12 or 13. If the sign of variation of the sense ratio SR (or sense voltage Vsns) is inverted when the sense position selected by the selector 93 is switched, the control unit 22 may determine that the resistance value Rsw of the upper-surface electrode 60 has varied.

By such control, variation of the resistance value Rsw of the upper-surface electrode 60 can be detected accurately. Upon operation of the semiconductor device 100, the selector 93 may select the second sense position 62. As described in FIGS. 10-13, the closer the sense position is to the first proximal position 81, the more greatly a sense ratio SR (or sense voltage Vsns) may vary due to variation of the resistance value Rsw of the upper-surface electrode 60. Accordingly, variation of the resistance value Rsw of the upper-surface electrode 60 can be detected at an early stage. Then, by switching the position to the first sense position 61 and measuring the sense ratio SR, it can be determined whether the variation of the sense ratio SR is due to variation of the resistance value of the upper-surface electrode 60.

The semiconductor device 100 may include, instead of the selector 93, the current sensing element 14, the MOSFET 18, the amplifier 16, the sense resistor 20, and the sense terminal SNS for each of the first sense position 61 and the second sense position 62. In this case, the sense ratio SR (or the sense voltage Vsns) at each of the first sense position 61 and the second sense position 62 can be measured in parallel.

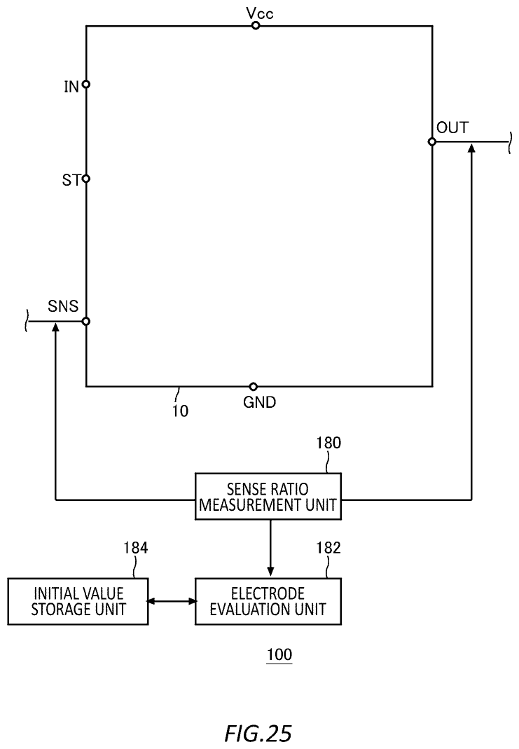

FIG. 25 shows another example of the semiconductor device 100. The semiconductor device 100 of the present example may further include at least some of a sense ratio measurement unit 180, an electrode evaluation unit 182, and an initial value storage unit 184. Each of the sense ratio measurement unit 180, the electrode evaluation unit 182, and the initial value storage unit 184 may be provided in the semiconductor substrate 10 or may be provided external to the semiconductor substrate 10. The control unit 22 may function as at least some of the sense ratio measurement unit 180, the electrode evaluation unit 182, and the initial value storage unit 184.

The sense ratio measurement unit 180 measures a sense ratio SR that indicates the ratio of sense current Isns flowing through the current sensing element 14 to output current Iout flowing through the output wiring line 13. When the output current Iout is constant, the sense ratio measurement unit 180 may measure the sense current Isns or sense voltage Vsns as an indicator of the sense ratio SR. When the output current Iout is not constant, the sense ratio measurement unit 180 may further measure the output current Iout. The sense ratio measurement unit 180 may measure the sense ratio SR at a set interval, may measure it in response to an instruction by a user or the like, or may measure it continuously.

The electrode evaluation unit 182 evaluates the upper-surface electrode 60 of the main element 12 based on the sense ratio SR measured by the sense ratio measurement unit 180. The electrode evaluation unit 182 may evaluate the upper-surface electrode 60 based on a deviation between the initial value and the measured value of the sense ratio SR. The electrode evaluation unit 182 may determine that the upper-surface electrode 60 has degraded if such a deviation (for example, ΔVsns) is equal to or greater than a reference value.

The initial value storage unit 184 stores an initial value of the sense ratio SR (or an indicator that indicates the sense ratio SR). The initial value storage unit 184 may store a value measured by the sense ratio measurement unit 180 at a time of shipment or the like of the semiconductor device 100, or may store a value set by a user or the like. The electrode evaluation unit 182 compares the measured value with the initial value of the sense ratio SR.

The control unit 22 shown in FIG. 1 may control the current to be flowed through the main element 12 based on the sense ratio SR measured by the sense ratio measurement unit 180. For example, the control unit 22 may reduce or block the current to be flowed through the main element 12 if variation of the sense ratio SR has become greater than a predetermined reference value. This allows the main element 12 to be protected. The control unit 22 may temporarily increase the output current Iout to be flowed through the main element 12 when variation of the sense ratio SR has become greater than a predetermined reference value. The electrode evaluation unit 182 may evaluate the upper-surface electrode 60 based on the sense ratio SR measured by the sense ratio measurement unit 180 while large current is flowing through the main element 12. Accordingly, if a symptom of degradation of the upper-surface electrode 60 is detected, it is possible to re-measure the degradation of the upper-surface electrode 60 by increasing the output current Iout to causing the variation of the sense ratio SR to be more significant. When the measurement with the increased current flowing through the main element 12 is completed, the control unit 22 may reduce the current to be flowed through the main element 12 to an original level.

The control unit 22 may control a resistance value of the sense resistor 20. For example, if variation of the sense voltage Vsns exceeds a reference value, the control unit 22 may temporarily increase the resistance value of the sense resistor 20. By temporarily increasing the resistance value of the sense resistor 20, a variation range of the sense voltage Vsns can be expanded, allowing accurate detection of the amount of variation of the sense voltage Vsns. When measurement of the amount of variation of the sense voltage Vsns is completed, the control unit 22 may reduce the resistance value of the sense resistor 20 to an original level. Thus, it is possible to suppress an increase of electrical power consumption while improving the measurement accuracy of the sense voltage Vsns. The sense resistor 20 may be a resistor external to the semiconductor device 100. That is, the sense resistor 20 may be an external resistor.

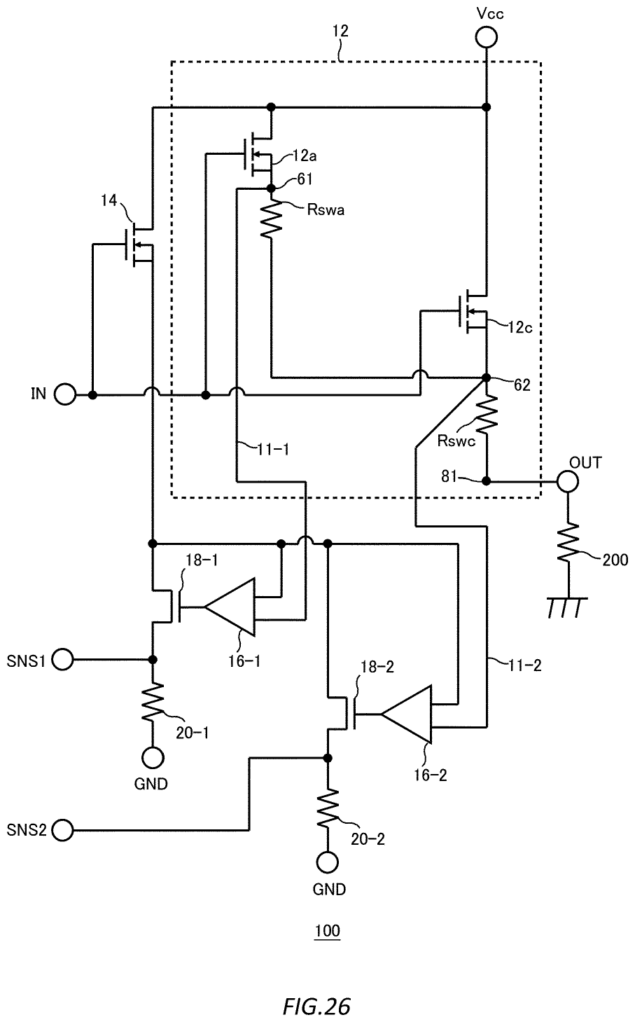

FIG. 26 shows another configuration example of the semiconductor device 100. In FIG. 26, an example of the equivalent circuit of the semiconductor device 100 and the load 200 is shown. In the semiconductor device 100 in FIG. 26, components other than the main element 12, the current sensing element 14, the sense wiring line 11, the amplifier 16, the MOSFET 18, sense resistor 20, and each terminal are omitted.

As is the case with the example described in FIG. 23, in the semiconductor device 100 of the present example, the first sense wiring line 11-1 is connected to the first sense position 61 and the second sense wiring line 11-2 is connected to the second sense position 62. The arrangement of the first sense position 61 and the second sense position 62 is similar to the example in FIG. 23. The first sense position 61 is arranged in the first region 111 (see FIG. 23) and the second sense position 62 is arranged in the second region 112 (see FIG. 23).

In FIG. 26, a main element 12a, a main element 12c, a resistance Rswa, and a resistance Rswc are shown as the structure of the main element 12. The resistance Rswa of the present example indicates a resistance from the first sense position 61 to the second sense position 62, and the resistance Rswc of the present example indicates a resistance from the second sense position 62 to the first proximal position 81. In addition, the main element 12a indicates a part of the main element 12 that is in the vicinity of the resistance Rswa, and the main element 12c indicates a part of the main element 12 that is in the vicinity of the resistance Rswc.

The semiconductor device 100 shown in FIG. 1 to FIG. 25 includes one sense terminal SNS. The semiconductor device 100 of the present example includes a first sense terminal SNS1 and a second sense terminal SNS2

The first sense terminal SNS1 outputs the potential at the first sense position 61, as described in FIG. 23 and the like, to the outside of the semiconductor device 100. The second sense terminal SNS2 outputs the potential at the second sense position 62, as described in FIG. 23 and the like, to the outside of the semiconductor device 100.

The semiconductor device 100 of the present example includes the amplifier 16, the MOSFET 18, and the sense resistor 20 for each of the first sense terminal SNS1 and the second sense terminal SNS2. The MOSFET 18-1 is connected between the source terminal of the current sensing element 14 and the ground potential GND. The sense resistor 20-1 is connected between the source terminal of the MOSFET 18-1 and the ground potential GND. The source terminal of the MOSFET 18-1 is connected to the first sense terminal SNS1. The MOSFET 18-2 is connected between the source terminal of the current sensing element 14 and the ground potential GND. The sense resistor 20-2 is connected between the source terminal of the MOSFET 18-2 and the ground potential GND. The source terminal of the MOSFET 18-2 is connected to the second sense terminal SNS2.

The amplifier 16-1 adjusts the voltage to be applied to the gate terminal of the MOSFET 18-1 so that the potential of the first sense wiring line 11-1 and the drain potential of the MOSFET 18-1 become the same. With this configuration, the first sense voltage Vsns1 at the first sense position 61 is output from the first sense terminal SNS1. The amplifier 16-2 adjusts the voltage to be applied to the gate terminal of the MOSFET 18-1 so that the potential of the second sense wiring line 11-2 and the drain potential of the MOSFET 18-2 become the same. With this configuration, the second sense voltage Vsns2 at the second sense position 62 is output from the second sense terminal SNS2.

The first sense voltage Vsns1 at the first sense terminal SNS1 before and after the increase in the resistance value Rsw of the upper-surface electrode 60 varies in the same way as the voltage at the first sense position 61-1 shown in FIG. 10. That is, as the resistance value Rsw increases, the first sense voltage Vsns1 decreases.

The second sense voltage Vsns2 at the second sense terminal SNS2 before and after the increase in the resistance value Rsw of the upper-surface electrode 60 varies in the same way as the voltage at the first sense position 61-3 shown in FIG. 12. That is, as the resistance value Rsw increases, the second sense voltage Vsns2 increases.

The semiconductor device 100 may further include the electrode evaluation unit 182 described in FIG. 25. The electrode evaluation unit 182 may be provided external to the semiconductor device 100. The electrode evaluation unit 182 of the present example evaluates the upper-surface electrode 60 of the main element 12 based on the difference between the first sense voltage Vsns1 output by the first sense terminal SNS1 and the second sense voltage Vsns2 output by the second sense terminal SNS2. As described above, according to the increase in the resistance value Rsw of the upper-surface electrode 60, one of the first sense voltage Vsns1 and the second sense voltage Vsns2 increases, and the other decreases. Thus, by calculating the difference between these, the variation of the first sense voltage Vsns1 and the variation of the second sense voltage Vsns2 can be detected, and sensitivity to detect the variation of the sense voltage relative to the increase in the resistance value Rsw can be improved.

The longer the distance between the first sense position 61 and the second sense position 62 (for example, LW1-LW2 in FIG. 23), the larger the resistance Rswa becomes, and the difference between the first sense voltage Vsns1 and the second sense voltage Vsns2 is increased. Said distance may be equal to or more than ¾ times, equal to or more than ⅞ times, equal to or more than 9/10 times, or equal to or more than 19/20 times the maximum distance LM (see FIG. 23).

The electrode evaluation unit 182 may evaluate the upper-surface electrode 60 based on the deviation between the initial value of said difference and the measured value of said difference. The electrode evaluation unit 182 may determine that the upper-surface electrode 60 has degraded if said deviation is equal to or greater than a reference value.

The semiconductor device 100 may further include the initial value storage unit 184 described in FIG. 25. The initial value storage unit 184 may be provide external to the semiconductor device 100. The initial value storage unit 184 stores the initial value of the difference between the first sense voltage Vsns1 and the second sense voltage Vsns2. The initial value storage unit 184 may store a value measured at a time of shipment or the like of the semiconductor device 100, or may store a value set by a user or the like. The electrode evaluation unit 182 may compare the initial value stored by the initial value storage unit 184 and the measured value.

The control unit 22 described in FIG. 1 and the like may control the current to be flowed through the main element 12 based on the evaluation result obtained in the electrode evaluation unit 182. The operation of the control unit 22 is similar to the example in FIG. 25. For example, the control unit 22 may reduce or block the current to be flowed through the main element 12 if the variation of the above-described difference from the initial value has become greater than a predetermined reference value. This allows the main element 12 to be protected.

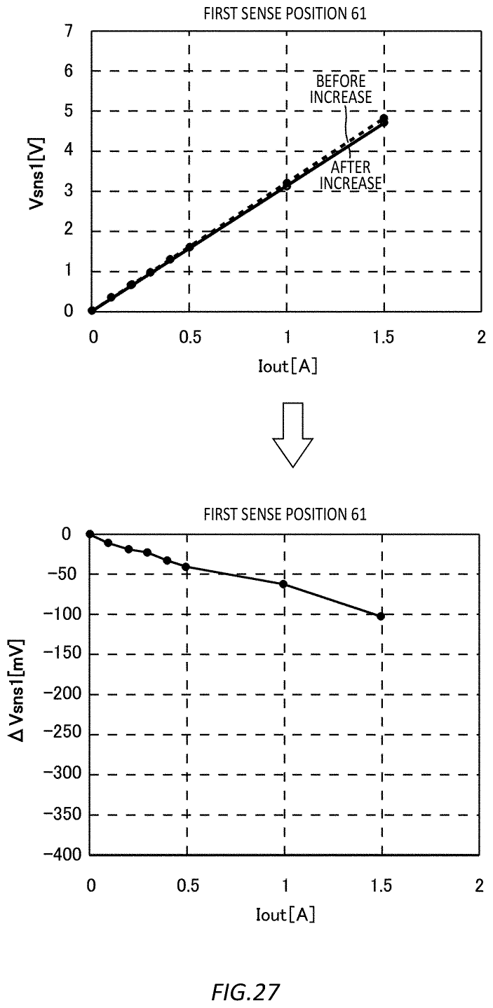

FIG. 27 shows variation of the first sense voltage Vsns1 before and after the increase in the resistance value Rsw of the upper-surface electrode 60. The upper graph in FIG. 27 indicates the relationships between the output current Iout and the first sense voltage Vsns1, one of which is before and another is after the increase in the resistance value Rsw of the upper-surface electrode 60. The upper graph in FIG. 27 is similar to the graph in FIG. 10.

The lower graph in FIG. 27 shows an amount of variation (first variation voltage ΔVsns1) of the first sense voltage Vsns1 after the increase in the resistance value Rsw relative to the first sense voltage Vsns1 before the increase in the resistance value Rsw. The minus on the vertical axis in said graph indicates that the first sense voltage Vsns1 after the increase in the resistance value Rsw has decreased relative to the first sense voltage Vsns1 before the increase in the resistance value Rsw.

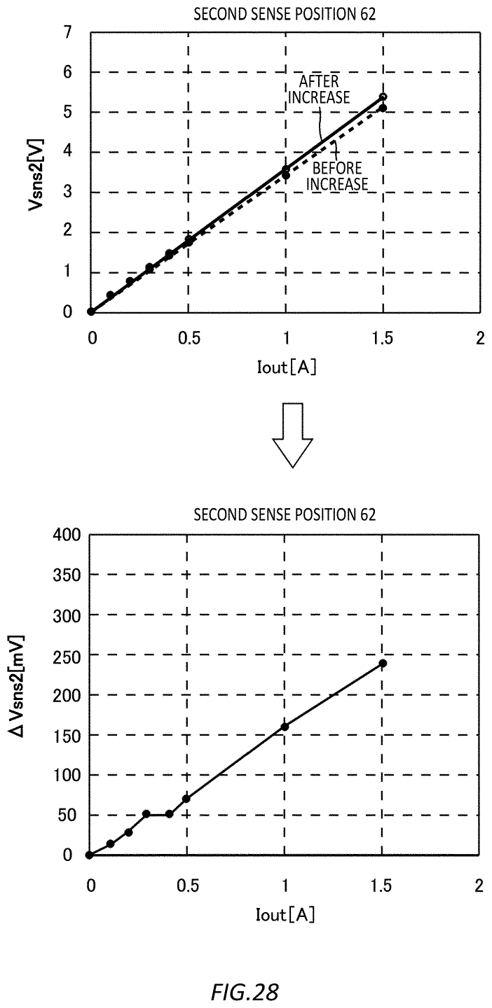

FIG. 28 shows variation of the second sense voltage Vsns2 before and after the increase in the resistance value Rsw of the upper-surface electrode 60. The upper graph in FIG. 28 indicates the relationships between the output current Iout and the second sense voltage Vsns2, one of which is before and another is after the increase in the resistance value Rsw of the upper-surface electrode 60. The upper graph in FIG. 28 is similar to the graph in FIG. 12.

The lower graph in FIG. 28 shows an amount of variation (second variation voltage ΔVsns2) of the second sense voltage Vsns2 after the increase in the resistance value Rsw relative to the second sense voltage Vsns2 before the increase in the resistance value Rsw. The plus on the vertical axis in said graph indicates that the second sense voltage Vsns2 after the increase in the resistance value Rsw has increased relative to the second sense voltage Vsns2 before the increase in the resistance value Rsw.

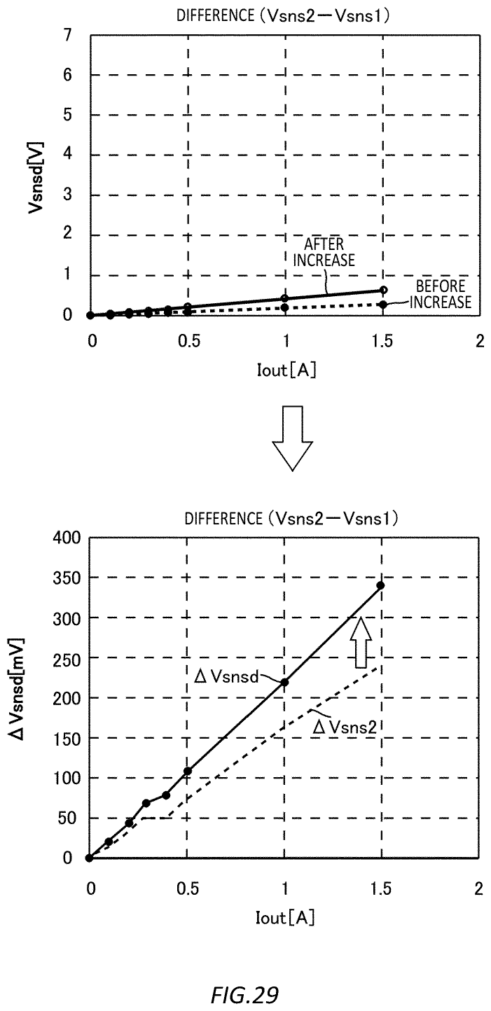

FIG. 29 shows variation of a difference voltage Vsnsd (=Vsns2−Vsns1) between the second sense voltage Vsns2 and the first sense voltage Vsns1 before and after the increase in the resistance value Rsw of the upper-surface electrode 60. The upper graph in FIG. 29 indicates the relationships between the output current Iout and the difference voltage Vsnsd, one of which is before and another is after the increase in the resistance value Rsw of the upper-surface electrode 60.

The lower graph in FIG. 29 shows an amount of variation (difference variation voltage ΔVsnsd) of the difference voltage Vsnsd after the increase in the resistance value Rsw relative to the difference voltage Vsnsd before the increase in the resistance value Rsw. The plus on the vertical axis in said graph indicates that the difference voltage Vsnsd after the increase in the resistance value Rsw has increased relative to the difference voltage Vsnsd before the increase in the resistance value Rsw. In said graph, the second variation voltage ΔVsns2 shown in FIG. 28 is represented by a dashed line. As shown in said graph, it is observed that the difference voltage vsnsd varies by a larger gain relative to the variation of the resistance value Rsw. Accordingly, the variation of the resistance value Rsw can be sensed with high sensitivity.

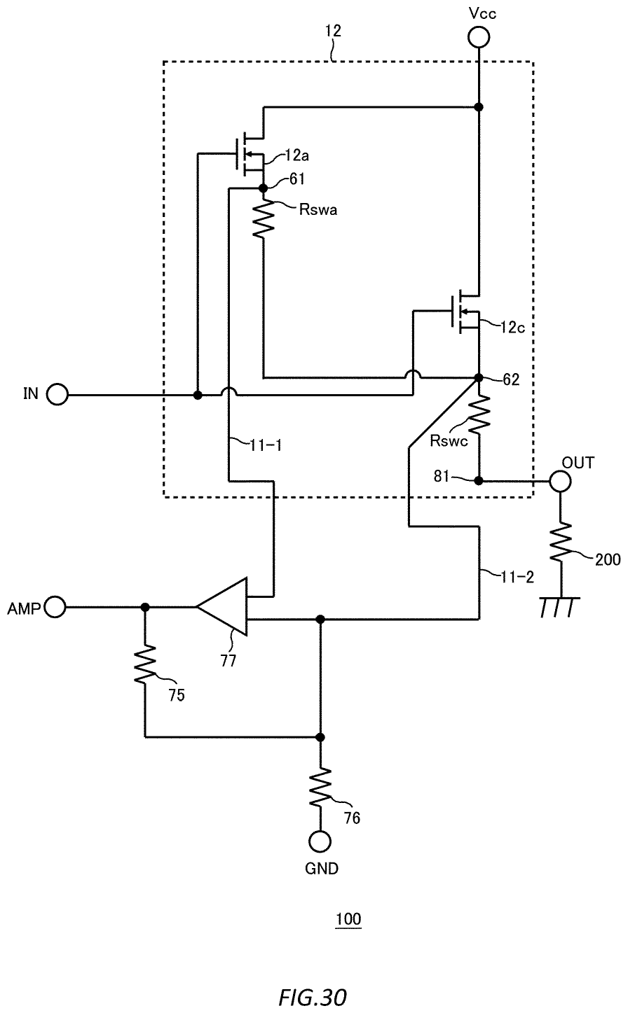

FIG. 30 shows another configuration example of the semiconductor device 100. In FIG. 30, an example of the equivalent circuit of the semiconductor device 100 and the load 200 is shown. In the semiconductor device 100 in FIG. 30, components other than the main element 12, a difference output portion 77, a resistor 75, a resistor 76, and each terminal are omitted. The structure of the main element 12 is similar to the example in FIG. 26.

As is the case with the example described in FIG. 26, in the semiconductor device 100 of the present example, the first sense wiring line 11-1 is connected to the first sense position 61 and the second sense wiring line 11-2 is connected to the second sense position 62. The arrangement of the first sense position 61 and the second sense position 62 is similar to the example in FIG. 26

The difference output portion 77 outputs the difference between the potential at the first sense position 61 transmitted by the first sense wiring line 11-1 and the potential at the second sense position 62 transmitted by the second sense wiring line 11-2. The difference output portion 77 of the present example is a differential amplifier circuit in which the first sense wiring line 11-1 is connected to a positive input terminal and the second sense wiring line 11-2 is connected to a negative input terminal.

The resistor 75 is connected between an output terminal of the difference output portion 77 and the negative input terminal. The resistor 76 is connected between the negative input terminal of the difference output portion 77 and a low potential terminal GND. The difference output portion 77 amplifies the difference between the potential at the first sense position 61 and the potential at the second sense position 62 by an amplification factor according to the resistance ratio between the resistor 75 the resistor 76, and outputs the amplified difference. When a resistance value of the resistor 75 is denoted as R75, and a resistance value of the resistor 76 is demoted as R76, the amplification factor G of the difference output portion 77 is expressed in the following expression.

$$G = 1 + R 76 / R 75$$

The semiconductor device 100 of the present example includes a difference output terminal AMP. The difference output terminal AMP is connected to the output terminal of the difference output portion 77. Since the semiconductor device 100 of the present example outputs the difference between the potential at the first sense position 61 and the potential at the second sense position 62, the degradation of upper-surface electrode 60 can be accurately detected by monitoring said difference.

If a current value flowing through the main element 12 is not to be sensed, the semiconductor device 100 may not include the current sensing element 14, the amplifier 16, the MOSFET 18, the sense resistor 20, and the sense terminal SNS. If the current value flowing through the main element 12 is to be sensed, the semiconductor device 100 may include the current sensing element 14, the amplifier 16, the MOSFET 18, the sense resistor 20, and the sense terminal SNS, although these are omitted in FIG. 30.

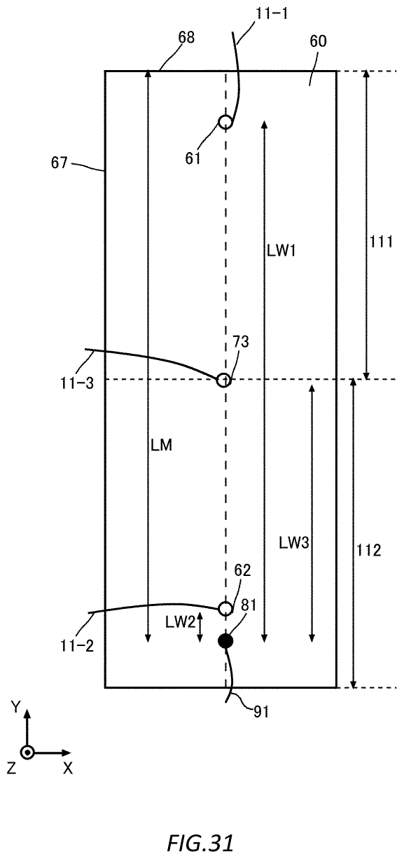

FIG. 31 shows another exemplary connection of the sense wiring line 11. The first sense wiring line 11-1, the second sense wiring line 11-2, and a third sense wiring line 11-3 are connected to the upper-surface electrode 60 of the present example. The first sense position 61 and the second sense position 62 at which the first sense wiring line 11-1 and the second sense wiring line 11-2 are respectively connected to the upper-surface electrode 60 are similar to the example in FIG. 23. A position at which the third sense wiring line 11-3 is connected to the upper-surface electrode 60 is denoted as the third sense position 73. A distance from the third sense position 73 to the first proximal position 81 is denoted as the third inter-wiring line distance LW3.

The third sense position 73 is arranged between the first sense position 61 and the second sense position 62. The first sense position 61, the second sense position 62, and the third sense position 73 may or may not be arranged on one straight line. The third sense position 73 may be arranged between the first sense position 61 and the second sense position 62 in a longitudinal direction (in the Y-axis direction in FIG. 31) of the upper-surface electrode 60.

The third sense position 73 may be arranged in a range in which the position Ymos is −10% to 10% (see FIG. 14). That is, the third sense position 73 may be arranged approximately in the center of the upper-surface electrode 60. The third sense position 73 may be arranged such that the distance to the first sense position 61 (LW1-LW3) and the distance to the second sense position 62 (LW3-LW2) become approximately equal. The difference between the distance (LW1−LW3) and the distance (LW3-LW2) may be equal to or less than 10% of the distance (LW3−LW2). By this arrangement of the third sense position 73, the sense voltage Vsns3 at the third sense position 73 hardly varies even when the resistance value Rsw of the upper-surface electrode 60 varies. Thus, the current value flowing through the main element 12 can be accurately sensed by sensing the third sense voltage Vsns3.

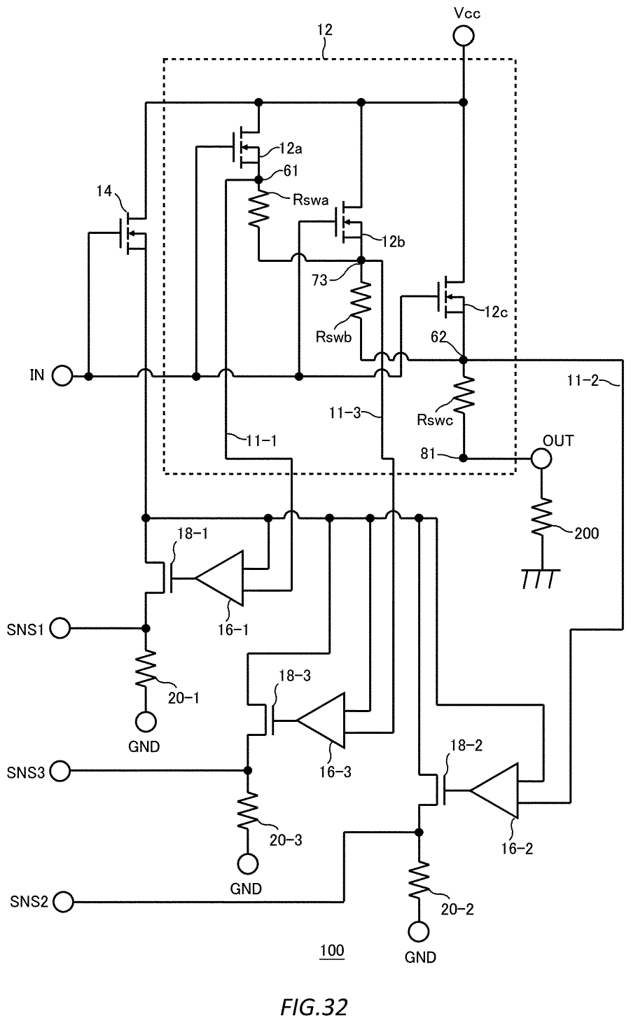

FIG. 32 shows an example of an equivalent circuit of the semiconductor device 100 described in FIG. 31. The semiconductor device 100 of the present example includes the amplifier 16-3, the MOSFET 18-3, the sense resistor 20-3, and the sense terminal SNS 3, in addition to the components shown in FIG. 26. The components in FIG. 32 that have the same reference numerals as those in FIG. 26 may have similar functions and configurations to those shown in FIG. 26 unless otherwise described.

The main element 12 of the present example is indicated by the main element 12a, the main element 12b, the main element 12c, the resistance Rswa, the resistance Rswb, and the resistance Rswc. The resistance Rswa of the present example indicates a resistance from the first sense position 61 to the third sense position 73, the resistance Rswb indicates a resistance from the third sense position 73 to the second sense position 62, and the resistance Rswc of the present example indicates a resistance from the second sense position 62 to the first proximal position 81. In addition, the main element 12a indicates a part of the main element 12 that is in the vicinity of the resistance Rswa, and the main element 12b indicates a part of the main element 12 that is in the vicinity of the resistance Rswb, and the main element 12c indicates a part of the main element 12 that is in the vicinity of the resistance Rswc.

The MOSFET 18-3 is connected between the source terminal of the current sensing element 14 and the ground potential GND. The sense resistor 20-3 is connected between the source terminal of the MOSFET 18-3 and the ground potential GND. The source terminal of the MOSFET 18-3 is connected to the third sense terminal SNS3.

The amplifier 16-3 adjusts the voltage to be applied to the gate terminal of the MOSFET 18-3 so that the potential of the third sense wiring line 11-3 and the drain potential of the MOSFET 18-3 become the same. With this configuration, the third sense voltage Vsns3 at the third sense position 73 is output from the third sense terminal SNS3. Also in the present example, the semiconductor device 100 may further include the electrode evaluation unit 182 described in FIG. 25. In addition, the difference output portion 77, the resistor 75, the resistor 76, and the difference output terminal AMP shown in FIG. 30 may be provided instead of the amplifier 16-1, the MOSFET 18-1, the sense resistor 20-1, the sense terminal SNS 1, the amplifier 16-2, the MOSFET 18-2, the sense resistor 20-2, and the sense terminal SNS 2 shown in FIG. 32.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such alterations or improvements are made can be included in the technical scope of the present invention.

What is claimed is:

1. A semiconductor device comprising:
a main element having an upper-surface electrode;
one or more output wiring lines that are connected to the upper-surface electrode; and
a first sense wiring line that is connected to a first sense position on the upper-surface electrode and that transmits potential at the first sense position, wherein
the one or more output wiring lines include a first proximal wiring line having a shortest distance between its connection position to the upper-surface electrode and the first sense position,
the first proximal wiring line is connected to a first proximal position on the upper-surface electrode, and
on the upper-surface electrode, a first inter-wiring line distance that is from the first sense position to the first proximal position is different from a half of a maximum distance that is from the first proximal position to an end of the upper-surface electrode.

2. The semiconductor device according to claim 1, further comprising:
a current sensing element through which current according to current flowing through the main element flows, wherein
the first sense wiring line applies potential at the first sense position to the current sensing element.

3. The semiconductor device according to claim 2, wherein the first inter-wiring line distance is equal to or more than 0 times and equal to or less than ¼ times the maximum distance.

4. The semiconductor device according to claim 2, wherein the first inter-wiring line distance is equal to or more than ¾ times and equal to or less than 1 times the maximum distance.

5. The semiconductor device according to claim 2, wherein
the upper-surface electrode has a rectangular shape having a shorter side in a first direction and a longer side in a second direction, and
the first sense position and the first proximal position are arranged side-by-side in the first direction.

6. The semiconductor device according to claim 2, wherein when the upper-surface electrode is divided equally into a plurality of regions by a straight line that is parallel to any side of the upper-surface electrode, the first sense position is arranged in a first region and the first proximal position is arranged in a second region.

7. The semiconductor device according to claim 2, wherein when the upper-surface electrode is divided equally into a plurality of regions by a straight line that is parallel to any side of the upper-surface electrode, the first sense position and the first proximal position are arranged in a same region.

8. The semiconductor device according to claim 2, wherein when the upper-surface electrode is divided equally into a plurality of regions by a straight line that is parallel to a first side of the upper-surface electrode and also divided equally into a plurality of regions by a straight line that is parallel to a second side that is not parallel to the first side, the first sense position is arranged in a first region and the first proximal position is arranged in a second region that is provided diagonally opposite to the first region.

9. The semiconductor device according to claim 2, wherein when the upper-surface electrode is divided equally into a plurality of regions by a straight line that is parallel to a first side of the upper-surface electrode and also divided equally into a plurality of regions by a straight line that is parallel to a second side that is not parallel to the first side, the first sense position and the first proximal position are arranged in a same region.

10. The semiconductor device according to claim 2, wherein
the one or more output wiring lines include a second wiring line having a second-shortest distance between its connection position to the upper-surface electrode and the first sense position, and
a distance between the connection position of the second wiring line and the first sense position is longer than a distance between the first proximal position and the first sense position.

11. The semiconductor device according to claim 2, further comprising:
a second sense wiring line that is connected to a second sense position on the upper-surface electrode and that is for applying potential at the second sense position to the current sensing element, wherein
on the upper-surface electrode, a second inter-wiring line distance that is from the second sense position to the first proximal position is different from the first inter-wiring line distance.

12. The semiconductor device according to claim 11, wherein when the upper-surface electrode is divided equally into a plurality of regions by a straight line that is parallel to any side of the upper-surface electrode, the first sense position is arranged in a first region and the second sense position is arranged in a second region.

13. The semiconductor device according to claim 12, further comprising:
a selector that selects either potential at the first sense position or potential at the second sense position, and applies it to the current sensing element.

14. The semiconductor device according to claim 12, further comprising:
a first sense terminal that outputs potential at the first sense position to outside of the semiconductor device;
a second sense terminal that outputs potential at the second sense position to outside of the semiconductor device.

15. The semiconductor device according to claim 14, further comprising:
a third sense wiring line that is connected to a third sense position between the first sense position and the second sense position on the upper-surface electrode; and
a third sense terminal that outputs potential at the third sense position to outside of the semiconductor device.

16. The semiconductor device according to claim 2, further comprising:
a sense ratio measurement unit that measures a sense ratio indicating a ratio of current flowing through the current sensing element to current flowing through the output wiring line; and
an electrode evaluation unit that evaluates the upper-surface electrode of the main element based on the sense ratio measured by the sense ratio measurement unit.

17. The semiconductor device according to claim 16, further comprising:
an initial value storage unit that stores an initial value of the sense ratio, wherein
the electrode evaluation unit compares a measured value with the initial value of the sense ratio.

18. The semiconductor device according to claim 16, further comprising:
a control unit that controls current to be flowed through the main element based on the sense ratio measured by the sense ratio measurement unit.

19. The semiconductor device according to claim 2, further comprising:
a sense resistor that is arranged between the current sensing element and a reference potential, wherein
a resistance value of the sense resistor is variable.

20. The semiconductor device according to claim 1, further comprising:
a second sense wiring line that is connected to a second sense position on the upper-surface electrode and that transmits potential at the second sense position; and
a difference output portion that outputs a difference between potential at the first sense position and potential at the second sense position, wherein
when the upper-surface electrode is divided equally into a plurality of regions by a straight line that is parallel to any side of the upper-surface electrode, the first sense position is arranged in a first region and the second sense position is arranged in a second region.
